(19) United States
(12) Patent Application Publication
(10) Pub. No.: US 2018/0171077 A1
(43) Pub. Date: Jun. 21, 2018

(54) POLYIMIDE PRECURSOR COMPOSITION AND POLYIMIDE COMPOSITION

(71) Applicant: UBE INDUSTRIES, LTD., Ube-shi (JP)

(72) Inventors: Takuya OKA, Ube-shi (JP); Yukinori KOHAMA, Ube-shi (JP); Ryoichi TAKASAWA, Ube-shi, Yamaguchi (JP); Nobuharu HISANO, Ube-shi (JP); Ken KAWAGISHI, Ichihara-shi (JP)

(21) Appl. No.: 15/735,287

(22) PCT Filed: Jun. 10, 2016
(86) PCT No.: PCT/JP2016/067453

§ 371 Date: Dec. 11, 2017

(30) Foreign Application Priority Data
Jun. 12, 2015 (JP) 2015-119719

(51) Int. Cl. C08G 73/10; C08K 3/26; B32B 17/06; B32B 27/28

(52) U.S. Cl. CPC C08G 73/1071; C08G 73/1067; C08G 73/1082; C08G 73/1078; C08G 73/10; C08K 3/26; H01L 27/1218; B32B 27/281; C08K 2003/262; B32B 2457/208; B32B 2307/7242; B32B 2457/12; B32B 17/064

(57) ABSTRACT

A polyimide precursor composition including a polyimide precursor, and a fine particle having an optical anisotropy; and a polyimide composition including a polyimide, and a fine particle having an optical anisotropy.

### TECHNICAL FIELD

The present invention relates to a polyimide composition which has a small retardation in the thickness direction and in the in-plane direction, and also has excellent properties such as transparency, mechanical properties, or heat resistance; and a precursor composition thereof. The present invention also relates to a polyimide film and a substrate, and the like, which have a small retardation in the thickness direction and in the in-plane direction, and also have excellent properties such as transparency, mechanical properties, or heat resistance.

### BACKGROUND ART

With the coming of an advanced information society, the developments of optical materials such as an optical fiber and an optical waveguide in the field of optical communications, and a liquid crystal oriented film and a protective film for a color-filter in the field of display devices have recently advanced. In the field of display devices, in particular, the study of a plastic substrate which is light-weight and excellent in flexibility as an alternative to a glass substrate, and the development of a display which is capable of being bent and rolled have been intensively conducted. Accordingly, there is need for a higher-performance optical material which may be used for such purposes.

Aromatic polyimides are intrinsically yellowish-brown-colored due to the intramolecular conjugation and the formation of the charge-transfer complex. Accordingly, as a means of reducing coloring, methods of developing transparency, for example, by introducing a fluorine atom into the molecule, imparting flexibility to the main chain, introducing a bulky group as a side chain, or the like to suppress the intramolecular conjugation and the formation of the charge-transfer complex have been proposed (for example, Patent Literature 1).

In addition, methods of developing transparency by the use of a semi-alicyclic or wholly-alicyclic polyimide which do not form a charge-transfer complex in principle have been also proposed (for example, Patent Literatures 2 to 5).

In some applications, particularly in the field of display devices, or the like, however, it is desired that the retardation in the thickness direction and in the in-plane direction should be reduced, in addition to having high transparency. A problem that color is not correctly displayed, or color is blurred, or a viewing angle is narrowed may arise when light passes through a film having a large retardation. Accordingly, a polyimide film which has a small retardation is required in the field of display devices, or the like, in particular.

Meanwhile, Patent Literature 6 discloses a non-birefringent optical resin material comprising a transparent polymer resin having an orientation birefringence which is caused by the alignment of the binding chains (specifically, polystyrene, polyphenylene oxide, polycarbonate, polyvinyl chloride, polymethyl methacrylate, polyethylene terephthalate, polyethylene) and a fine particle of strontium carbonate produced by a certain production method which is dispersed in the polymer resin, wherein the fine particle of strontium carbonate is aligned statistically in the polymer resin such that the orientation birefringence of the polymer resin is reduced. More specifically, in the non-birefringent optical resin material described in Patent Literature 6, the fine particle of strontium carbonate is aligned statistically along the direction of the hot-stretching by adding the fine particle of strontium carbonate, which is a needle crystal, into a polymer film, and then hot-stretching the polymer film. Alternatively, the fine particle of strontium carbonate is aligned by the flow of the polymer during melting by adding the rod-shaped crystal fine particle of strontium carbonate into a polymer pellet, and then using the polymer pellet in an injection molding method or an extrusion molding method.

Patent Literature 7 and Patent Literature 8 disclose a fine particle of strontium carbonate having an orientation birefringence, which is used to disperse the fine particle in a polymer resin having a birefringence and thereby reduce the birefringence.

In addition, Patent Literature 9 discloses a process for producing an optical film, comprising adding a dispersant (specifically, phosphate dispersant) to a fine particle having an optical anisotropy (specifically, strontium carbonate fine particle) in an amount of 5 wt % or more, dissolving a transparent polymer (specifically, polycarbonate, N-methylmaleimide-isobutene copolymer) in a fine particle dispersion in which the fine particle is dispersed in a solvent, and forming a film from the obtained the fine particle-dispersed polymer solution by a solution casting method for filmization.

Patent Literature 10 discloses a process for producing a retardation film, comprising stretching a thermoplastic polymer film which comprises a polyimide having a certain structure, to obtain a retardation film.

### CITATION LIST

### Patent Literature

Patent Literature 1: JP-A-2010-538103

Patent Literature 2: JP-A-2012-41529

Patent Literature 3: WO2014/046064A1

Patent Literature 4: JP-A-2009-286706

Patent Literature 5: JP-A-2014-92775

Patent Literature 6: JP-A-2004-35347

Patent Literature 7: JP-A-2006-21987

Patent Literature 8: JP-A-2014-80360

Patent Literature 9: JP-A-2007-140011

Patent Literature 10; JP-A-2006-3715

### SUMMARY OF INVENTION

### Technical Problem

An object of the present invention is to provide a polyimide composition which may be easily produced, and has a small retardation in the thickness direction and in the in-plane direction, and also has excellent transparency, mechanical properties, or heat resistance, or the like; and a precursor composition thereof. An object of the present invention is also to provide a varnish from which a polyimide composition having a small retardation in the thickness direction and in the in-plane direction, and also having excellent transparency, mechanical properties, or heat resistance, or the like may be obtained; and a polyimide film and a substrate which have a small retardation in the thickness direction and in the in-plane direction, and also have excellent transparency, mechanical properties, or heat resistance, or the like.

### Solution to Problem

The present invention relates to the following items.

1. A polyimide precursor composition, comprising

a polyimide precursor (A1); and

a fine particle having an optical anisotropy (B).

2. The polyimide precursor composition as described in “1”, wherein the polyimide precursor (A1) comprises at least one repeating unit represented by the following chemical formula (1);

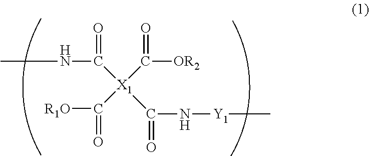

wherein X₁ is a tetravalent group having an aromatic ring or an alicyclic structure; Y₁ is a divalent group having an aromatic ring or an alicyclic structure; and R₁ and R₂ are each independently hydrogen, an alkyl group having 1 to 6 carbon atoms, or an alkylsilyl group having 3 to 9 carbon atoms.
3. The polyimide precursor composition as described in “2”, wherein the content of the repeating unit represented by the chemical formula (1) in which X₁ is a tetravalent group having an alicyclic structure and Y₁ is a divalent group having an alicyclic structure is 50 mol % or less relative to the total repeating units.
4. The polyimide precursor composition as described in “2”, wherein in the chemical formula (1), X₁ is a tetravalent group having an aromatic ring and Y₁ is a divalent group having an aromatic ring.
5. The polyimide precursor composition as described in “2”, wherein in the chemical formula (1), X₁ is a tetravalent group having an alicyclic structure and Y₁ is a divalent group having an aromatic ring.
6. The polyimide precursor composition as described in “2”, wherein in the chemical formula (1), X₁ is a tetravalent group having an aromatic ring and Y₁ is a divalent group having an alicyclic structure.
7. The polyimide precursor composition as described in any one of “1” to “6”, wherein the fine particle having an optical anisotropy (B) is strontium carbonate.
8. A polyimide composition, comprising

a polyimide (A2); and

a fine particle having an optical anisotropy (B).

9. The polyimide composition as described in “8”, wherein the polyimide (A2) comprises at least one repeating unit represented by the following chemical formula (7):

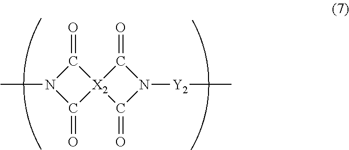

wherein X₂ is a tetravalent group having an aromatic ring or an alicyclic structure; and Y₂ is a divalent group having an aromatic ring or an alicyclic structure.
10. A polyimide composition obtained from the polyimide precursor composition as described in any one of “1” to “7”.
11. A polyimide film consisting of a polyimide composition obtained from the polyimide precursor composition as described in any one of “1” to “7”, or the polyimide composition as described in any one of “8” to “9”.
12. A polyimide film laminate, comprising

the polyimide film as described in “11”; and

at least one glass layer.

13. A polyimide film laminate, comprising

the polyimide film as described in “11”; and

at least one gas barrier layer.

14. A polyimide film laminate, comprising

the polyimide film as described in “11”; and

at least one thin-film transistor.

15. The polyimide film laminate as described in “12” or “13”, comprising

the polyimide film as described in “11”; and

at least one conductive layer.

16. A varnish, comprising

a polyimide precursor (A1) or a polyimide (A2);

a fine particle having an optical anisotropy (B); and

a solvent.

17. A polyimide composition obtained using the varnish as described in “16”
18. A polyimide film obtained using the varnish as described in “16”.
19. A film (for example, substrate, or the like) for a display, a touch panel, or a solar battery, comprising

a polyimide composition obtained from the polyimide precursor composition as described in any one of “1” to “7”, or the polyimide composition as described in any one of “8” to “9”.

20. A display device, a sensor device, a photoelectric conversion device, or an optical device, comprising

a polyimide composition obtained from the polyimide precursor composition as described in any one of “1” to “7”, or the polyimide composition as described in any one of “8” to “9”.

21. A fine particle powder having an optical anisotropy, which is surface-treated with a polyamic acid (A3) comprising a repeating unit represented by the following chemical formula (8):

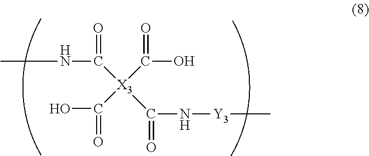

wherein X₃ is a tetravalent group having an aromatic ring or an alicyclic structure; and Y₃ is a divalent group having an aromatic ring or an alicyclic structure; with the proviso that the carboxyl group (—COOH) in the formula may form a salt with a base.
22. A fine particle dispersion, comprising

a polyamic acid (A3) comprising a repeating unit represented by the following chemical formula (8):

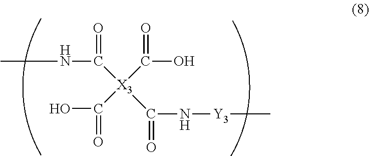

wherein X₃ is a tetravalent group having an aromatic ring or an alicyclic structure; and Y₃ is a divalent group having an aromatic ring or an alicyclic structure; with the proviso that the carboxyl group (—COOH) in the formula may form a salt with a base;

a fine particle having an optical anisotropy (B); and

a solvent (C).

### Advantageous Effects of Invention

According to the present invention, there may be provided a polyimide composition which may be easily produced, and has a small retardation in the thickness direction and in the in-plane direction, and also has excellent transparency, mechanical properties, or heat resistance, or the like; and a precursor composition thereof.

According to the present invention, there may be also provided a varnish (polyimide precursor solution composition, polyimide solution composition) from which a polyimide composition having a small retardation in the thickness direction and in the in-plane direction, and also having excellent transparency, mechanical properties, or heat resistance, or the like may be obtained.

In addition, according to the present invention, there may be provided a polyimide film and a substrate which have a small retardation in the thickness direction and in the in-plane direction, and also have excellent transparency, mechanical properties, or heat resistance, or the like. The polyimide composition obtained from the polyimide precursor composition of the present invention, or the polyimide composition of the present invention has excellent properties, and therefore may be suitably used for the formation of a substrate for a display, a touch panel, a solar battery, or the like. The polyimide composition obtained from the polyimide precursor composition of the present invention, or the polyimide composition of the present invention may also be suitably used for the application of substrates in other devices (semiconductor device, and the like), and also may be suitably used for the application of cover films, color filters, and the like, in addition to substrates, in display devices such as various displays, sensor devices such as a touch panel, photoelectric conversion devices such as a solar battery, other optical devices, and the like.

According to the present invention, not only the retardation in the in-plane direction but also the retardation in the thickness direction may be easily reduced by merely adding a fine particle having an optical anisotropy to a varnish used for the production of a polyimide composition (i.e., a polyimide precursor solution composition, a polyimide solution composition) without aligning the needle- or rod-shaped fine particle having an optical anisotropy such as strontium carbonate in one direction by hot-stretching a film of a polyimide composition, or by melting a polyimide composition and injection-molding or extrusion-molding the polyimide composition, or the like, that is, without a special treatment for the alignment of the fine particle. Additionally, in the stretching, the injection molding method, or the extrusion molding method, the fine particle having an optical anisotropy such as strontium carbonate is aligned together with the polymer molecule by external stress such as stretching or molding of the polymer. In such a molding process, however, it is difficult to precisely control the flowability of the polymer, or achieve a uniform flow of the polymer, and therefore it is difficult to precisely control the alignment of the polymer molecule and the fine particle having an optical anisotropy, and it is difficult to obtain a good optical film. In contrast thereto, according to the present invention wherein a polyimide precursor comprising at least one repeating unit represented by the chemical formula (1) preferably in an amount of 70 mol % or more relative to the total repeating units, or a polyimide comprising at least one repeating unit represented by the chemical formula (7) preferably in an amount of 70 mol % or more relative to the total repeating units is used, in particular, the fine particle having an optical anisotropy may be efficiently aligned and a good optical film may be easily produced without performing a special operation such as stretching. When a polyimide precursor composition comprising a polyimide precursor (polyamic acid) and a fine particle having an optical anisotropy is imidized, in particular, a water molecule is eliminated and the alignment of the molecular chains proceeds during the imidization reaction, and therewith the fine particle having an optical anisotropy can be aligned more effectively and better. Accordingly, although the retardation of the obtained polyimide composition in the thickness direction and in the in-plane direction may be reduced even when a polyimide precursor other than the above is imidized, the effect is great in the case of a polyimide precursor having the composition as described above, which is preferred.

The polyimide film/base laminate, or the polyimide film of the present invention may be suitably obtained, for example, using the above-described polyimide precursor composition, and the above-described polyimide composition (for example, a composition of a solution in which a polyimide is dissolved) as the starting material.

In addition, according to the present invention, there may be provided a surface-treated fine particle powder having an optical anisotropy, and a fine particle dispersion comprising a fine particle having an optical anisotropy and a solvent, which may be suitably used for the polyimide composition and the precursor composition thereof.

### DESCRIPTION OF EMBODIMENTS

The polyimide precursor composition of the present invention comprises a polyimide precursor (A1) and a fine particle having an optical anisotropy (B). The polyimide precursor (A1) is, for example, the one comprising at least one repeating unit represented by the chemical formula (1) as described below.

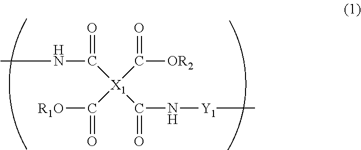

wherein X₁ is a tetravalent group having an aromatic ring or an alicyclic structure; Y₁ is a divalent group having an aromatic ring or an alicyclic structure; and R₁ and R₂ are each independently hydrogen, an alkyl group having 1 to 6 carbon atoms, or an alkylsilyl group having 3 to 9 carbon atoms.

The polyimide precursor (A1), however, may be a partially-imidized polyamic acid, or the like, in which the imidization partially proceeds and a repeating unit with an imide structure is comprised.

The polyimide composition of the present invention comprises a polyimide (A2) and a fine particle having an optical anisotropy (B). The polyimide (A2) is, for example, the one comprising at least one repeating unit represented by the chemical formula (7) as described below.

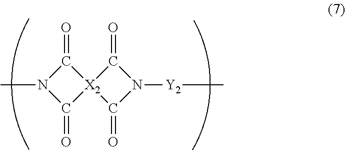

wherein X₂ is a tetravalent group having an aromatic ring or an alicyclic structure; and Y₂ is a divalent group having an aromatic ring or an alicyclic structure.

The polyimide precursor (A1) to be used in the polyimide precursor composition of the present invention, the polyimide (A2) to be used in the polyimide composition of the present invention, and the fine particle having an optical anisotropy (B) to be used in the polyimide precursor composition of the present invention and the polyimide composition of the present invention will be described below in detail.

### <Polyimide Precursor (A1)>

The polyimide precursor (A1) is, for example, the one comprising at least one repeating unit represented by the chemical formula (1).

It is preferred, but not limited thereto, that X₁ is a tetravalent group having an aromatic ring and Y₁ is a divalent group having an aromatic ring in the chemical formula (1) of the polyimide precursor (A1), because the obtained polyimide composition has excellent heat resistance. It is also preferred that X₁ is a tetravalent group having an alicyclic structure and Y₁ is a divalent group having an aromatic ring, because the obtained polyimide composition has excellent heat resistance and simultaneously has excellent transparency. It is also preferred that X₁ is a tetravalent group having an aromatic ring and Y₁ is a divalent group having an alicyclic structure, because the obtained polyimide composition has excellent heat resistance and simultaneously has excellent dimensional stability.

In view of the properties of the obtained polyimide composition, for example, transparency, mechanical properties, or heat resistance, or the like, the content of the repeating unit represented by the chemical formula (1) in which X₁ is a tetravalent group having an alicyclic structure and Y₁ is a divalent group having an alicyclic structure is preferably 50 mol % or less, more preferably 30 mol % or less, or less than 30 mol %, more preferably 10 mol % or less, relative to the total repeating units.

In one embodiment, in the polyimide precursor (A1), the content of one or more repeating units of the chemical formula (1) in which X₁ is a tetravalent group having an aromatic ring and Y₁ is a divalent group having an aromatic ring is preferably 50 mol % or more, more preferably 70 mol % or more, more preferably 80 mol % or more, more preferably 90 mol % or more, particularly preferably 100 mol %, in total, relative to the total repeating units. In this embodiment, it is preferred that the polyimide precursor (A1) contains a fluorine atom in the case where a polyimide composition having high transparency, in particular, is required. In other words, it is preferred that the polyimide precursor (A1) comprises one or more of repeating units of the chemical formula (1) in which X₁ is a tetravalent group having a fluorine atom-containing aromatic ring and/or repeating units of the chemical formula (1) in which Y₁ is a divalent group having a fluorine atom-containing aromatic ring.

In one embodiment, in the polyimide precursor (A1), the content of one or more repeating units of the chemical formula (1) in which X₁ is a tetravalent group having an alicyclic structure and Y₁ is a divalent group having an aromatic ring is preferably 50 mol % or more, more preferably 70 mol % or more, more preferably 80 mol % or more, more preferably 90 mol % or more, particularly preferably 100 mol %, in total, relative to the total repeating units.

In one embodiment, in the polyimide precursor (A1), the content of one or more repeating units of the chemical formula (1) in which X₁ is a tetravalent group having an aromatic ring and Y₁ is a divalent group having an alicyclic structure is preferably 50 mol % or more, more preferably 70 mol % or more, more preferably 80 mol % or more, more preferably 90 mol % or more, particularly preferably 100 mol %, in total, relative to the total repeating units.

As the tetravalent group having an aromatic ring as X₁, a tetravalent group having an aromatic ring which has 6 to 40 carbon atoms is preferred.

Examples of the tetravalent group having an aromatic ring include the following groups.

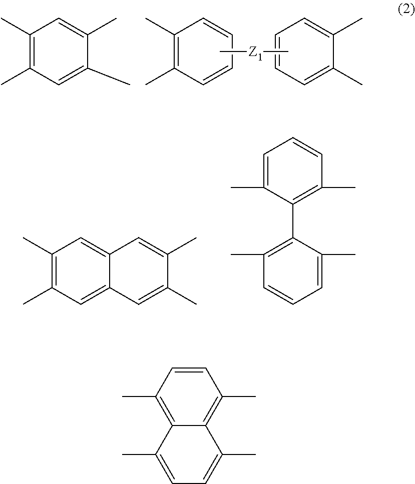

wherein Z₁ is a direct bond, or any one of the following divalent groups:

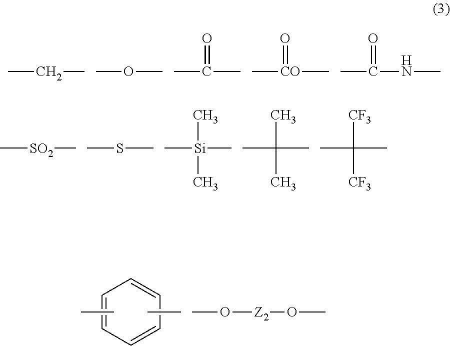

with the proviso that Z₂ in the formula is a divalent organic group.

Specific examples of Z₂ include an aliphatic hydrocarbon group having 2 to 24 carbon atoms, and an aromatic hydrocarbon group having 6 to 24 carbon atoms.

Because the obtained polyimide composition may have both high heat resistance and high transparency, the following group is particularly preferred as the tetravalent group having an aromatic ring.

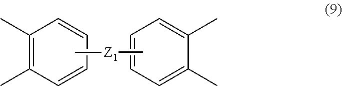

wherein Z₁ is a direct bond, or a hexafluoroisopropylidene bond.

Because the obtained polyimide composition may have high heat resistance, high transparency, and low coefficient of linear thermal expansion, Z₁ herein is more preferably a direct bond.

Examples of the tetracarboxylic acid component to provide a repeating unit of the chemical formula (1) in which X₁ is a tetravalent group having an aromatic ring include 2,2-bis(3,4-dicarboxyphenyl)hexafluoropropane, 4-(2,5-dioxotetrahydrofuran-3-yl)-1,2,3,4-tetrahydronaphthalene-1,2-dicarboxylic acid, pyromellitic acid, 3,3′,4,4′-benzophenone tetracarboxylic acid, 3,3′,4,4′-biphenyl tetracarboxylic acid, 2,3,3′,4′-biphenyl tetracarboxylic acid, 4,4′-oxydiphthalic acid, bis(3,4-dicarboxyphenyl)sulfone, m-terphenyl-3,4,3′,4′-tetracarboxylic acid, p-terphenyl-3,4,3′,4′-tetracarboxylic acid, biscarboxyphenyl dimethylsilane, bisdicarboxyphenoxydiphenyl sulfide, and sulfonyl diphthalic acid, and derivatives thereof, including tetracarboxylic dianhydride, tetracarboxylic acid silyl ester, tetracarboxylic acid ester, and tetracarboxylic acid chloride. Examples of the tetracarboxylic acid component to provide a repeating unit of the chemical formula (1) in which X₁ is a tetravalent group having a fluorine atom-containing aromatic ring include 2,2-bis(3,4-dicarboxyphenyl)hexafluoropropane, and derivatives thereof, including tetracarboxylic dianhydride, tetracarboxylic acid silyl ester, tetracarboxylic acid ester, and tetracarboxylic acid chloride. The tetracarboxylic acid component may be used alone or in combination of a plurality of types.

As the tetravalent group having an alicyclic structure as X₁, a tetravalent group having an alicyclic structure which has 4 to 40 carbon atoms is preferred, and it is more preferred that the group has at least one aliphatic 4- to 12-membered ring, more preferably an aliphatic 4-membered ring or an aliphatic 6-membered ring.

Additionally, because both high heat resistance and high transparency may be achieved, it is preferred that the tetravalent group having an alicyclic structure as X₁ has at least one aliphatic 6-membered ring and does not have an aromatic ring in the chemical structure. There may be a plurality of 6-membered rings in the X₁ (tetravalent group having an alicyclic structure) and a plurality of 6-membered rings may be composed of two or more common carbon atoms. The 6-membered ring may also be a bridged ring type in which the carbon atoms constituting the ring (inside the 6-membered ring) are linked to each other to further form a ring.

As the X₁ (tetravalent group having an alicyclic structure), the one having a 6-membered ring structure with high symmetry is preferred because a dense packing of polymer chains is possible and the polyimide has excellent solvent resistance, heat resistance, and mechanical strength. Additionally, it is more preferred that in the X₁ (tetravalent group having an alicyclic structure), a plurality of 6-membered rings is composed of two or more common carbon atoms, and the 6-membered ring has the carbon atoms constituting the ring which are linked to each other to further form a ring, because good heat resistance, solvent resistance, and low coefficient of linear thermal expansion of the polyimide may be easily achieved.

Preferred examples of the tetravalent group having an aliphatic 4-membered ring or an aliphatic 6-membered ring include the following groups.

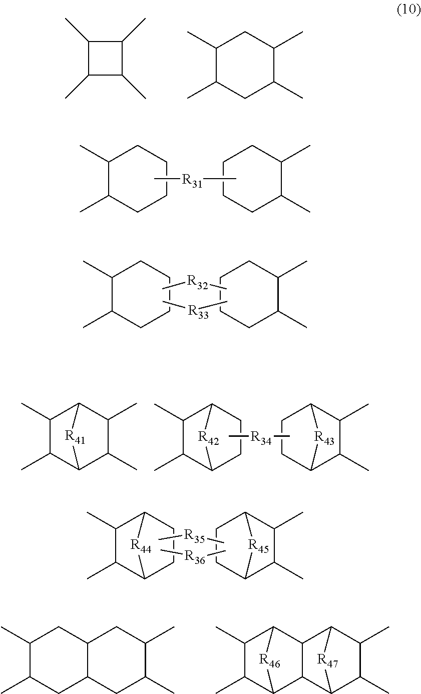

wherein R₃₁ to R₃₆ are each independently a direct bond, or a divalent organic group; and R₄₁ to R₄₇ each independently represent one selected from the group consisting of groups represented by the formulas: —CH₂—, —CH═CH—, —CH₂CH₂—, —O— and —S—.

Specific examples of R₃₁, R₃₂, R₃₃, R₃₄, R₃₅ and R₃₆ include a direct bond, or an aliphatic hydrocarbon group having 1 to 6 carbon atoms, or an oxygen atom (—O—), a sulfur atom (—S—), a carbonyl bond, an ester bond, and an amide bond.

Because the obtained polyimide may have high heat resistance, high transparency, and low coefficient of linear thermal expansion, the following groups are particularly preferred as the tetravalent group having an alicyclic structure.

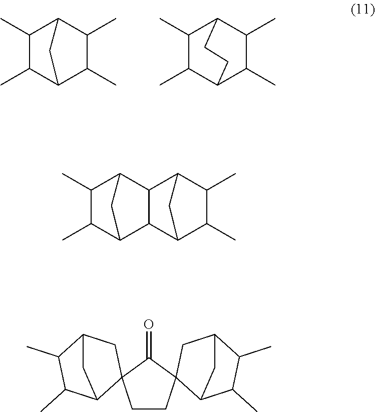

Examples of the tetracarboxylic acid component to provide a repeating unit of the chemical formula (1) in which X₁ is a tetravalent group having an alicyclic structure include 1,2,3,4-cyclobutane tetracarboxylic acid, isopropylidenediphenoxybisphthalic acid, cyclohexane-1,2,4,5-tetracarboxylic acid, [1,1′-bi(cyclohexane)]-3,3′,4,4′-tetracarboxylic acid, [1,1′-bi(cyclohexane)]-2,3,3′,4′-tetracarboxylic acid, [1,1′-bi(cyclohexane)]-2,2′,3,3′-tetracarboxylic acid, 4,4′-methylenebis(cyclohexane-1,2-dicarboxylic acid), 4,4′-(propane-2,2-diyl)bis(cyclohexane-1,2-dicarboxylic acid), 4,4′-oxybis(cyclohexane-1,2-dicarboxylic acid), 4,4′-thiobis(cyclohexane-1,2-dicarboxylic acid), 4,4′-sulfonyl bis(cyclohexane-1,2-dicarboxylic acid), 4,4′-(dimethylsilanediyl)bis (cyclohexane-1,2-dicarboxylic acid), 4,4′-(tetrafluoropropane-2,2-diyl)bis (cyclohexane-1,2-dicarboxylic acid), octahydropentalene-1,3,4,6-tetracarboxylic acid, bicyclo[2.2.1]heptane-2,3,5,6-tetracarboxylic acid, 6-(carboxymethyl)bicyclo[2.2.1]heptane-2,3,5-tricarboxylic acid, bicyclo[2.2.2]octane-2,3,5,6-tetracarboxylic acid, bicyclo[2.2.2]octa-5-ene-2,3,7,8-tetracarboxylic acid, tricyclo[4.2.2.02,5]decane-3,4,7,8-tetracarboxylic acid, tricyclo[4.2.2.02,5]deca-7-ene-3,4,9,10-tetracarboxylic acid, 9-oxatricyclo[4.2.1.02,5]nonane-3,4,7,8-tetracarboxylic acid, norbornane-2-spiro-α-cyclopentanone-α′-spiro-2″-norbornane-5,5″,6,6″-tetracarboxylic acid, (4arH,8acH)-decahydro-1t,4t:5c,8c-dimethanonaphthalene-2c, 3c, 6c, 7c-tetracarboxylic acid, and (4arH,8acH)-decahydro-1t,4t:5c,8c-dimethanonaphthalene-2t,3t,6c,7c-tetracarboxylic acid, and derivatives thereof, including tetracarboxylic dianhydride, tetracarboxylic acid silyl ester, tetracarboxylic acid ester, and tetracarboxylic acid chloride. The tetracarboxylic acid component may be used alone or in combination of a plurality of types.

As the divalent group having an aromatic ring as Y₁, a divalent group having an aromatic ring which has 6 to 40 carbon atoms, more preferably 6 to 20 carbon atoms, is preferred.

Examples of the divalent group having an aromatic ring include the following groups.

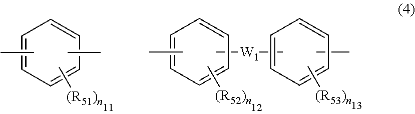

wherein W₁ is a direct bond, or a divalent organic group; n₁₁ to n₁₃ each independently represent an integer of 0 to 4; and R₅₁, R₅₂ and R₅₃ are each independently an alkyl group having 1 to 6 carbon atoms, a halogen group, a hydroxyl group, a carboxyl group, or a trifluoromethyl group.

Specific examples of W₁ include divalent groups represented by the formula (5) as described below, and divalent groups represented by the formula (6) as described below.

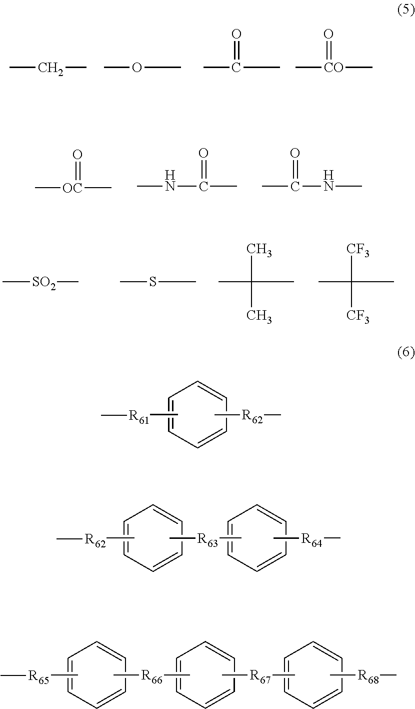

wherein R₆₁ to R₆₈ in the formula (6) each independently represent any one of the divalent groups represented by the formula (5).

Because the obtained polyimide may have high heat resistance, high transparency, and low coefficient of linear thermal expansion, W₁ herein is particularly preferably a direct bond, or one selected from the group consisting of groups represented by the formulas: —NHCO—, —CONH—, —COO— and —OCO—. In addition, W₁ is particularly preferably any one of the divalent groups represented by the formula (5) in which R₆₁ to R₆₈ are a direct bond, or one selected from the group consisting of groups represented by the formulas: —NHCO—, —CONH—, —COO— and —OCO—.

Examples of the diamine component to provide a repeating unit of the chemical formula (1) in which Y₁ is a divalent group having an aromatic ring include p-phenylenediamine, m-phenylenediamine, benzidine, 3,3′-diamino-biphenyl, 2,2′-bis(trifluoromethyl)benzidine, 3,3′-bis(trifluoromethyl) benzidine, m-tolidine, 4,4′-diaminobenzanilide, 3,4′-diaminobenzanilide, N,N′-bis(4-aminophenyl)terephthalamide, N,N′-p-phenylenebis(p-amino benzamide), 4-aminophenoxy-4-diaminobenzoate, bis(4-aminophenyl) terephthalate, biphenyl-4,4′-dicarboxylic acid bis(4-aminophenyl)ester, p-phenylenebis(p-aminobenzoate), bis(4-aminophenyl)-[1,1′-biphenyl]-4,4′-dicarboxylate, [1,1′-biphenyl]-4,4′-diyl bis(4-aminobenzoate), 4,4′-oxydianiline, 3,4′-oxydianiline, 3,3′-oxydianiline, p-methylenebis(phenylenediamine), 1,3-bis(4-aminophenoxy)benzene, 1,3-bis(3-aminophenoxy)benzene, 1,4-bis(4-aminophenoxy)benzene, 4,4′-bis(4-aminophenoxy)biphenyl, 4,4′-bis(3-amino phenoxy)biphenyl, 2,2-bis(4-(4-aminophenoxy)phenyl)hexafluoropropane, 2,2-bis(4-aminophenyl)hexafluoropropane, bis(4-aminophenyl)sulfone, 3,3′-bis(trifluoromethyl)benzidine, 3,3′-bis((aminophenoxy)phenyl)propane, 2,2′-bis(3-amino-4-hydroxyphenyl)hexafluoropropane, bis(4-(4-aminophenoxy) diphenyl)sulfone, bis(4-(3-aminophenoxy)diphenyl)sulfone, octafluorobenzidine, 3,3′-dimethoxy-4,4′-diaminobiphenyl, 3,3′-dichloro-4,4′-diaminobiphenyl, 3,3′-difluoro-4,4′-diaminobiphenyl, 2,4-bis(4-aminoanilino)-6-amino-1,3,5-triazine, 2,4-bis(4-aminoanilino)-6-methylamino-1,3,5-triazine, 2,4-bis(4-aminoanilino)-6-ethylamino-1,3,5-triazine, and 2,4-bis(4-amino anilino)-6-anilino-1,3,5-triazine. Examples of the diamine component to provide a repeating unit of the chemical formula (1) in which Y₁ is a divalent group having a fluorine atom-containing aromatic ring include 2,2′-bis (trifluoromethyl)benzidine, 3,3′-bis(trifluoromethyl)benzidine, 2,2-bis[4-(4-aminophenoxy)phenyl]hexafluoropropane, 2,2-bis(4-aminophenyl) hexafluoropropane, and 2,2′-bis(3-amino-4-hydroxyphenyl)hexafluoropropane. The diamine component may be used alone or in combination of a plurality of types.

As the divalent group having an alicyclic structure as Y₁, a divalent group having an alicyclic structure which has 4 to 40 carbon atoms is preferred, and it is more preferred that the group has at least one aliphatic 4- to 12-membered ring, more preferably an aliphatic 6-membered ring.

Examples of the divalent group having an alicyclic structure include the following groups.

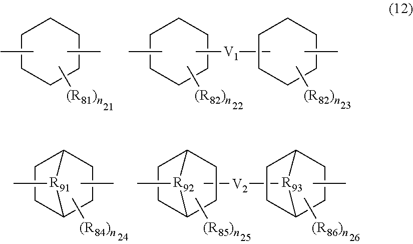

wherein V₁ and V₂ are each independently a direct bond, or a divalent organic group; n₂₁ to n₂₆ each independently represent an integer of 0 to 4; R₈₁ to R₈₆ are each independently an alkyl group having 1 to 6 carbon atoms, a halogen group, a hydroxyl group, a carboxyl group, or a trifluoromethyl group; and R₉₁, R₉₂ and R₉₃ are each independently one selected from the group consisting of groups represented by the formulas: —CH₂—, —CH═CH—, —CH₂CH₂—, —O— and —S—.

Specific examples of V₁ and V₂ include divalent groups represented by the formula (5) as described above.

Because the obtained polyimide may have both high heat resistance and low coefficient of linear thermal expansion, the following group is particularly preferred as the divalent group having an alicyclic structure.

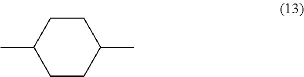

Among them, the following group is preferred as the divalent group having an alicyclic structure.

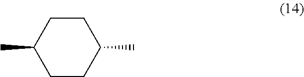

Examples of the diamine component to provide a repeating unit of the chemical formula (1) in which Y₁ is a divalent group having an alicyclic structure include 1,4-diaminocyclohexane, 1,4-diamino-2-methylcyclohexane, 1,4-diamino-2-ethylcyclohexane, 1,4-diamino-2-n-propylcyclohexane, 1,4-diamino-2-isopropylcyclohexane, 1,4-diamino-2-n-butylcyclohexane, 1,4-diamino-2-isobutylcyclohexane, 1,4-diamino-2-sec-butylcyclohexane, 1,4-diamino-2-tert-butylcyclohexane, 1,2-diaminocyclohexane, 1,3-diamino cyclobutane, 1,4-bis(aminomethyl)cyclohexane, 1,3-bis(aminomethyl) cyclohexane, diaminobicycloheptane, diaminomethylbicycloheptane, diaminooxybicycloheptane, diaminomethyloxybicycloheptane, isophoronediamine, diaminotricyclodecane, diaminomethyltricyclodecane, bis(aminocyclohexyl)methane, bis(aminocyclohexyl)isopropylidene, 6,6′-bis(3-aminophenoxy)-3,3,3′,3′-tetramethyl-1,1′-spirobiindane, and 6,6′-bis(4-aminophenoxy)-3,3,3′,3′-tetramethyl-1,1′-spirobiindane. The diamine component may be used alone or in combination of a plurality of types.

The polyimide precursor (A1) which comprises at least one repeating unit represented by the chemical formula (1) may comprise other repeating units other than the repeating units represented by the chemical formula (1).

Any other known aliphatic tetracarboxylic acids, or the like, and known aliphatic diamines may be used, without limitation, as the tetracarboxylic acid component and the diamine component to provide the other repeating unit. The other tetracarboxylic acid component may also be used alone or in combination of a plurality of types. The other diamine component may also be used alone or in combination of a plurality of types.

The content of the other repeating unit other than the repeating units represented by the chemical formula (1) is preferably 30 mol % or less, or less than 30 mol %, more preferably 20 mol % or less, more preferably 10 mol % or less, relative to the total repeating units.

In the chemical formula (1) of the polyimide precursor (A1), R₁ and R₂ are each independently hydrogen, an alkyl group having 1 to 6 carbon atoms, preferably having 1 to 3 carbon atoms, or an alkylsilyl group having 3 to 9 carbon atoms. In the case where R₁ and R₂ are hydrogen, a polyimide tends to be easily produced therefrom.

As for R₁ and R₂, the types of the functional groups and the introduction ratio of the functional groups may be changed by the production method as described later.

According to the chemical structures which R₁ and R₂ have, the polyimide precursor (A1) of the present invention (polyimide precursor comprising at least one repeating unit represented by the chemical formula (1)) may be classified into

1) polyamic acid (R₁ and R₂ are hydrogen),

2) polyamic acid ester (at least part of R₁ and R₂ is alkyl group), and

3) 4) polyamic acid silyl ester (at least part of R₁ and R₂ is alkylsilyl group).

Each class of the polyimide precursor (A1) of the present invention may be easily produced by the production methods as described below. However, the method for producing the polyimide precursor (A1) of the present invention is not limited to the production methods as described below.

1) Polyamic Acid

The polyimide precursor (A1) of the present invention may be suitably obtained, in the form of a polyimide precursor solution composition, by reacting a tetracarboxylic dianhydride as a tetracarboxylic acid component and a diamine component in a substantially equimolar amount, preferably in a molar ratio of the diamine component to the tetracarboxylic acid component[molar number of the diamine component/molar number of the tetracarboxylic acid component] of 0.90 to 1.10, more preferably 0.95 to 1.05, in a solvent at a relatively low temperature of 120° C. or less, for example, while suppressing the imidization.

More specifically, the polyimide precursor may be obtained by dissolving the diamine in an organic solvent or water, adding the tetracarboxylic dianhydride to the resulting solution gradually while stirring the solution, and then stirring the solution at 0° C. to 120° C., preferably 5° C. to 80° C., for 1 hour to 72 hours, although the production method is not limited thereto. When they are reacted at 80° C. or more, the molecular weight may vary depending on the temperature history in the polymerization and the imidization may proceed by heat, and therefore the polyimide precursor may not be stably produced. The sequence of the addition of the diamine and the tetracarboxylic dianhydride in the production method as described above is preferred because the molecular weight of the polyimide precursor is apt to increase. Meanwhile, the sequence of the addition of the diamine and the tetracarboxylic dianhydride in the production method as described above may be reversed, and the sequence is preferred because the amount of the precipitate is reduced. When water is used as the solvent, an imidazole such as 1,2-dimethylimidazole, or a base such as triethylamine is preferably added thereto preferably in an amount of 0.8 equivalents or more relative to the carboxyl group of the formed polyamic acid (polyimide precursor).

2) Polyamic Acid Ester

A diester dicarboxylic acid chloride may be obtained by reacting a tetracarboxylic dianhydride and an arbitrary alcohol to provide a diester dicarboxylic acid, and then reacting the diester dicarboxylic acid and a chlorinating agent (thionyl chloride, oxalyl chloride, and the like). The polyimide precursor may be obtained by stirring the diester dicarboxylic acid chloride and a diamine at −20° C. to 120° C., preferably −5° C. to 80° C., for 1 hour to 72 hours. When they are reacted at 80° C. or more, the molecular weight may vary depending on the temperature history in the polymerization and the imidization may proceed by heat, and therefore the polyimide precursor may not be stably produced. The polyimide precursor may also be easily obtained by dehydrating/condensing a diester dicarboxylic acid and a diamine by the use of a phosphorus-based condensing agent, a carbodiimide condensing agent, or the like.

The polyimide precursor obtained by the method is stable, and therefore may be subjected to purification, including reprecipitation in which a solvent such as water and alcohols is added thereto.

3) Polyamic Acid Silyl Ester (Indirect Method)

A silylated diamine may be obtained by reacting a diamine and a silylating agent in advance. The silylated diamine may be purified by distillation, or the like, as necessary. And then, the polyimide precursor may be obtained by dissolving the silylated diamine in a dehydrated solvent, adding a tetracarboxylic dianhydride to the resulting solution gradually while stirring the solution, and then stirring the solution at 0° C. to 120° C., preferably 5° C. to 80° C., for 1 hour to 72 hours. When they are reacted at 80° C. or more, the molecular weight may vary depending on the temperature history in the polymerization and the imidization may proceed by heat, and therefore the polyimide precursor may not be stably produced.

4) Polyamic Acid Silyl Ester (Direct Method)

The polyimide precursor may be obtained by mixing a polyamic acid solution obtained by the method 1) and a silylating agent, and then stirring the resulting mixture at 0° C. to 120° C., preferably 5° C. to 80° C., for 1 hour to 72 hours. When they are reacted at 80° C. or more, the molecular weight may vary depending on the temperature history in the polymerization and the imidization may proceed by heat, and therefore the polyimide precursor may not be stably produced.

As for the silylating agent to be used in the method 3) and the method 4), the use of a silylating agent containing no chlorine is preferred because it is unnecessary to purify the silylated polyamic acid, or the obtained polyimide. Examples of the silylating agent containing no chlorine atom include N,O-bis(trimethylsilyl)trifluoroacetamide, N,O-bis(trimethylsilyl) acetamide, and hexamethyldisilazane. Among them, N,O-bis(trimethylsilyl) acetamide, and hexamethyldisilazane are particularly preferred, because they contain no fluorine atom and are inexpensive.

Meanwhile, in the silylation reaction of the diamine in the method 3), an amine catalyst such as pyridine, piperidine and triethylamine may be used so as to accelerate the reaction. The catalyst may be used, as it is, as a catalyst for the polymerization of the polyimide precursor.

As the solvent (C) used in the production of the polyimide precursor (A1), water, or aprotic solvents such as N,N-dimethylformamide, N,N-dimethylacetamide, N-methyl-2-pyrrolidone, 1,3-dimethyl-2-imidazolidinone and dimethyl sulfoxide, for example, are preferred. However, any solvent may be used without any trouble on the condition that the starting monomer components and the formed polyimide precursor can be dissolved in the solvent, and therefore the solvent is not limited to the structures. As the solvent, water, or amide solvents such as N,N-dimethylformamide, N,N-dimethylacetamide and N-methylpyrrolidone; cyclic ester solvents such as γ-butyrolactone, γ-valerolactone, δ-valerolactone, γ-caprolactone, ε-caprolactone and α-methyl-γ-butyrolactone; carbonate solvents such as ethylene carbonate and propylene carbonate; glycol solvents such as triethylene glycol; phenol solvents such as m-cresol, p-cresol, 3-chlorophenol and 4-chlorophenol; acetophenone, 1,3-dimethyl-2-imidazolidinone, sulfolane, dimethylsulfoxide, and the like may be preferably employed. In addition, other common organic solvents, namely, phenol, o-cresol, butyl acetate, ethyl acetate, isobutyl acetate, propyleneglycol methyl acetate, ethyl cellosolve, butyl cellosolve, 2-methyl cellosolve acetate, ethyl cellosolve acetate, butyl cellosolve acetate, tetrahydrofuran, dimethoxyethane, diethoxyethane, dibutyl ether, diethylene glycol dimethyl ether, methyl isobutyl ketone, diisobutyl ketone, cyclopentanone, cyclohexanone, methyl ethyl ketone, acetone, butanol, ethanol, xylene, toluene, chlorobenzene, turpentine, mineral spirits, petroleum naphtha-based solvents, and the like may be used. The solvent may be used in combination of a plurality of types.

The logarithmic viscosity of the polyimide precursor (A1) in a N,N-dimethylacetamide solution at a concentration of 0.5 g/dL at 30° C. may be preferably 0.2 dL/g or more, more preferably 0.3 dL/g or more, particularly preferably 0.4 dL/g or more, although the logarithmic viscosity is not limited thereto. When the logarithmic viscosity is 0.2 dL/g or more, the molecular weight of the polyimide precursor is high, and therefore the obtained polyimide may have excellent mechanical strength and heat resistance.

<Polyimide (A2)>

The polyimide (A2), which is not particularly limited thereto, is obtained from the polyimide precursor (A1) and is, for example, the one comprising at least one repeating unit represented by the chemical formula (7).

The chemical formula (7) corresponds to the chemical formula (1), and X₁ corresponds to X₂ and Y₁ corresponds to Y₂. Examples of X₂ and Y₂ in the chemical formula (7) include those listed as X₁ and Y₁ in the chemical formula (1) and the preferred ones are also the same as X₁ and Y₁.

It is preferred, but not limited thereto, that X₂ is a tetravalent group having an aromatic ring and Y₂ is a divalent group having an aromatic ring in the chemical formula (7) of the polyimide (A2), because the polyimide has excellent heat resistance. It is also preferred that X₂ is a tetravalent group having an alicyclic structure and Y₂ is a divalent group having an aromatic ring, because the polyimide has excellent heat resistance and simultaneously has excellent transparency. It is also preferred that X₂ is a tetravalent group having an aromatic ring and Y₂ is a divalent group having an alicyclic structure, because the polyimide has excellent heat resistance and simultaneously has excellent dimensional stability.

For obtaining a polyimide composition which has a small retardation in the thickness direction and in the in-plane direction, and also has excellent properties such as transparency, mechanical properties, or heat resistance, the polyimide (A2) is preferably a polyimide obtained from an aromatic tetracarboxylic acid component and an aromatic diamine, which preferably contains a fluorine atom, or a polyimide obtained from an alicyclic tetracarboxylic acid component and an aromatic diamine, or a polyimide obtained from an aromatic tetracarboxylic acid component and an alicyclic diamine. The tetracarboxylic acid component includes tetracarboxylic acid, and tetracarboxylic acid derivatives including tetracarboxylic dianhydride, tetracarboxylic acid silyl ester, tetracarboxylic acid ester, and tetracarboxylic acid chloride.

In view of the properties of the polyimide composition, for example, transparency, mechanical properties, or heat resistance, or the like, the content of the repeating unit represented by the chemical formula (7) in which X₂ is a tetravalent group having an alicyclic structure and Y₂ is a divalent group having an alicyclic structure is preferably 50 mol % or less, more preferably 30 mol % or less, or less than 30 mol %, more preferably 10 mol % or less, relative to the total repeating units.

In one embodiment, in the polyimide (A2), the content of one or more repeating units of the chemical formula (7) in which X₂ is a tetravalent group having an aromatic ring and Y₂ is a divalent group having an aromatic ring is preferably 50 mol % or more, more preferably 70 mol % or more, more preferably 80 mol % or more, more preferably 90 mol % or more, particularly preferably 100 mol %, in total, relative to the total repeating units. In this embodiment, it is preferred that the polyimide (A2) contains a fluorine atom in the case where high transparency is required, in particular. In other words, it is preferred that the polyimide (A2) comprises one or more of repeating units of the chemical formula (7) in which X₂ is a tetravalent group having a fluorine atom-containing aromatic ring and/or repeating units of the chemical formula (7) in which Y₂ is a divalent group having a fluorine atom-containing aromatic ring.

In one embodiment, in the polyimide (A2), the content of one or more repeating units of the chemical formula (7) in which X₂ is a tetravalent group having an alicyclic structure and Y₂ is a divalent group having an aromatic ring is preferably 50 mol % or more, more preferably 70 mol % or more, more preferably 80 mol % or more, more preferably 90 mol % or more, particularly preferably 100 mol %, in total, relative to the total repeating units.

In one embodiment, in the polyimide (A2), the content of one or more repeating units of the chemical formula (7) in which X₂ is a tetravalent group having an aromatic ring and Y₂ is a divalent group having an alicyclic structure is preferably 50 mol % or more, more preferably 70 mol % or more, more preferably 80 mol % or more, more preferably 90 mol % or more, particularly preferably 100 mol %, in total, relative to the total repeating units.

The polyimide (A2) which comprises at least one repeating unit represented by the chemical formula (7) may comprise one or more of other repeating units other than the repeating units represented by the chemical formula (7).

The content of the other repeating unit other than the repeating units represented by the chemical formula (7) is preferably 30 mol % or less, or less than 30 mol %, more preferably 20 mol % or less, more preferably 10 mol % or less, relative to the total repeating units.

The polyimide (A2) of the present invention may be produced by imidizing the polyimide precursor (A1) of the present invention (i.e., subjecting the polyimide precursor (A1) to the dehydration/ring closure reaction). The imidization method is not particularly limited, and any known thermal imidization or chemical imidization method may be suitably applied. The method for producing the polyimide (A2) will be described later as a method for producing the polyimide composition of the present invention.

<Fine Particle Having an Optical Anisotropy (B)>

As the fine particle having an optical anisotropy (B), any material may be used, without limitation, on the condition that it has an optical anisotropy.

The fine particle having an optical anisotropy (B) is preferably a carbonate, for example. More specifically, the fine particle having an optical anisotropy (B) is preferably a fine particle of one or more carbonates selected from the group consisting of strontium carbonate, calcium carbonate, magnesium carbonate, cobalt carbonate, and manganese carbonate, more preferably strontium carbonate.

Examples of the form (crystal structure) of the carbonate include aragonite, calcite, vaterite, and amorphous.

In the present invention, the fine particle having an optical anisotropy (B) preferably has an anisotropic shape such as needle-shape or rod-shape, and is more preferably a fine needle- or rod-shaped carbonate, particularly preferably a fine needle- or rod-shaped strontium carbonate.

The fine particle having an optical anisotropy (B) preferably has an average aspect ratio of 1.5 or more, more preferably 2 or more, particularly preferably 2.2 or more. The upper limit of the average aspect ratio is generally, but not limited to, about 5. The aspect ratio is expressed by the ratio of the length to the diameter of the fine particle (B) (length/diameter).

In view of the transparency of the obtained polyimide composition, or the like, the fine particle having an optical anisotropy (B) preferably has an average long diameter length of 100 nm or less, more preferably 70 nm or less, particularly preferably 30 nm to 40 nm.

In the present invention, in the fine particle having an optical anisotropy (B), the content of the needle-shaped particle having a long diameter length of 200 nm or more is preferably 5% or less, more preferably 3% or less, more preferably 1% or less, particularly preferably 0%, based on the number of particles.

The fine particle having an optical anisotropy (B) such as strontium carbonate fine particle may be surface-treated with a surface treatment agent.

In the present invention, a fine particle having an optical anisotropy (B) which is surface-treated with the surface treatment agent described in JP-A-2014-80360, that is, a fine particle having an optical anisotropy (B) in which the surface of the particle is treated with a polycarboxylic acid having a polyoxyalkylene group as the side-chain, or an anhydride thereof, and an amine having a polyoxyalkylene group and a hydrocarbon group may be suitably used, for example. A fine particle having an optical anisotropy (B) which is surface-treated with the surface treatment agent described in JP-A-2014-80360 may be obtained by surface-treating any fine particle having an optical anisotropy (B), which is not limited to the needle-shaped strontium carbonate particle having a specific shape, by the method described in JP-A-2014-80360. However, the one wherein the needle-shaped strontium carbonate particle having a specific shape as described in JP-A-2014-80360 is subjected to the surface treatment is particularly preferred.

In one embodiment, the surface treatment agent for the fine particle having an optical anisotropy (B) preferably has a carboxylic acid as the functional group, and is particularly preferably a polyamic acid. The fine particle powder having an optical anisotropy and surface-treated with a polyamic acid of the present invention will be described below in detail.

<Fine Particle Powder Having an Optical Anisotropy and Surface-Treated with a Polyamic Acid>

In one embodiment of the present invention, the fine particle having an optical anisotropy (B) such as strontium carbonate fine particle to be used is preferably a fine particle powder having an optical anisotropy, which is surface-treated with a polyamic acid (A3) comprising a repeating unit represented by the following chemical formula (8):

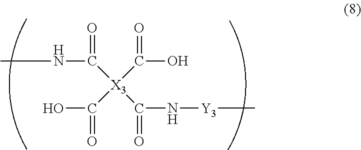

wherein X₃ is a tetravalent group having an aromatic ring or an alicyclic structure; and Y₃ is a divalent group having an aromatic ring or an alicyclic structure; with the proviso that the carboxyl group (—COOH) in the formula may form a salt with a base.

The polyamic acid (A3) comprising a repeating unit represented by the chemical formula (8) herein is preferably, but not limited to, a polyimide precursor (A1) which is a polyamic acid (polyimide precursor comprising a repeating unit represented by the chemical formula (1) wherein R₁ and R₂ in the chemical formula (1) are hydrogen). The chemical formula (8) corresponds to the chemical formula (1), and X₁ corresponds to X₃ and Y₁ corresponds to Y₃. Examples of X₃ and Y₃ in the chemical formula (8) include those listed as X₁ and Y₁ in the chemical formula (1) and the preferred ones are also the same as X₁ and Y₁.

Examples of the base which forms a salt with the carboxyl group in the chemical formula (8) include amines, alkali metal hydroxides, and alkaline earth metal hydroxides. Amines are preferred because they are volatilized by subsequent heat treatment, or the like, and tertiary amines are more preferred, and tertiary amines having a ring structure are particularly preferred. Additionally, pyridine and imidazole derivatives are preferred, and imidazole derivatives are more preferred, because they are effective as a catalyst for imidization.

The fine particle powder having an optical anisotropy which is surface-treated with the polyamic acid (A3) comprising a repeating unit represented by the chemical formula (3) may be obtained, for example, as follows.

Firstly, in the same way as in the production method of “1) Polyamic acid” as the method for producing the polyimide precursor (A1), a solution of the polyamic acid (A3) is obtained by reacting a tetracarboxylic dianhydride as a tetracarboxylic acid component and a diamine component in a substantially equimolar amount, preferably in a molar ratio of the diamine component to the tetracarboxylic acid component [molar number of the diamine component/molar number of the tetracarboxylic acid component] of 0.90 to 1.10, more preferably 0.95 to 1.05, in a solvent at a relatively low temperature of 120° C. or less, for example, while suppressing the imidization. It is preferred that the total amount of the tetracarboxylic acid component and the diamine component is 5 mass % or more, preferably 10 mass % or more, more preferably 15 mass % or more, relative to the total amount of the solvent, the tetracarboxylic acid component and the diamine component. Additionally, it is generally preferred that the total amount of the tetracarboxylic acid component and the diamine component is 60 mass % or less, preferably 50 mass % or less, relative to the total amount of the solvent, the tetracarboxylic acid component and the diamine component.

The solvent used herein in the production of the solution of the polyamic acid (A3) is not particularly limited, on the condition that the polyamic acid (A3) can be dissolved in the solvent, and any solvent may be used without any trouble. Examples of the solvent used herein include the same as the solvent (C) used in the production of the polyimide precursor (A1) as described above, and for the reason as described later, water is preferably used as the solvent.

Next, a dispersion (slurry) in which the fine particle having an optical anisotropy (B) surface-treated with the polyamic acid is dispersed is obtained by mixing the fine particle having an optical anisotropy (B) or a dispersion thereof (slurry) and the obtained solution of the polyamic acid (A3) at 0° C. to 120° C. for 0.1 hour to 72 hours, for example. The amount of the polyamic acid (A3) to be added is preferably, but not limited to, 0.5 parts by weight or more, preferably 1 parts by weight or more, more preferably 3 parts by weight or more, particularly preferably 5 parts by weight or more, relative to 100 parts by weight of the fine particle having an optical anisotropy (B), because the dispersibility of the fine particle having an optical anisotropy (B) is good. Meanwhile, the amount of the polyamic acid (A3) to be added is preferably 50 parts by weight or less, preferably 30 parts by weight or less, more preferably 25 parts by weight or less, particularly preferably 15 parts by weight or less, relative to 100 parts by weight of the fine particle having an optical anisotropy (B), because during the dispersion, the hydrolysis of the polyamic acid, or the like, is minimized. The method for adding the solution of the polyamic acid (A3) to the fine particle having an optical anisotropy (B) and dispersing is not particularly limited, and any known dispersion method may be suitably applied.

In the case where a dispersion of the fine particle having an optical anisotropy (B) is used, the solvent of the dispersion is not particularly limited, on the condition that the polyamic acid (A3) can be dissolved in the solvent, and any solvent may be used without any trouble. Examples of the solvent of the dispersion include the same as the solvent used in the production of the polyimide precursor (A1) as described above (the same as the solvent of the solution of the polyamic acid), and water is preferably used as the solvent. The solvent of the dispersion of the fine particle having an optical anisotropy (B) may be the same as, or different from the solvent of the solution of the polyamic acid (A3).

When both of the solvents used herein, that is, the solvent of the solution of the polyamic acid (A3) and the solvent of the dispersion of the fine particle having an optical anisotropy (B) are water, the fine particle having an optical anisotropy (B) which is surface-treated with the polyamic acid (A3) is obtained in the form of an aqueous slurry in the production, and therefore an operation such as solvent replacement may be simplified, which is preferred.

In view of the transparency of the obtained polyimide composition, or the like, it is usually preferred that only the polyamic acid (A3) is used as the dispersant, although a common general dispersant may be used together herein in order to efficiently disperse the fine particle having an optical anisotropy (B) in the solvent, or the solution of the polyamic acid (A3).

The fine particle powder having an optical anisotropy which is surface-treated with the polyamic acid (A3) may be obtained by drying the dispersion (slurry) by a known method, for example, by heating the dispersion (slurry) at 50° C. to 120° C. for 0.1 hour to 12 hours in air, nitrogen, or a vacuum to dry it, after the fine particle having an optical anisotropy (B) is mixed with and dispersed in the solution of the polyamic acid (A3) in this way to carry out the surface treatment.

In the present invention, the dispersion (slurry) in which the fine particle having an optical anisotropy (B) is dispersed in the solution of the polyamic acid (A3), that is, the fine particle dispersion of the present invention which comprises a polyamic acid (A3) comprising a repeating unit represented by the chemical formula (8), a fine particle having an optical anisotropy (B), and a solvent may also be used for the production of a polyimide precursor composition or a polyimide composition without drying it, as it is.

<Fine Particle Dispersion Comprising a Polyamic Acid, a Fine Particle Having an Optical Anisotropy, and a Solvent>

In one embodiment of the present invention, the dispersion of the fine particle having an optical anisotropy (B) to be used is preferably a fine particle dispersion which comprises a polyamic acid (A3) comprising a repeating unit represented by the chemical formula (8), a fine particle having an optical anisotropy (B), and a solvent.

As the polyamic acid (A3), the polyamic acid (A3) comprising a repeating unit represented by the chemical formula (8) presented as the surface treatment agent for the fine particle having an optical anisotropy (B) is preferred.

The fine particle dispersion of the present invention may be obtained by preparing a solution of the polyamic acid (A3), and then mixing the fine particle having an optical anisotropy (B) or a dispersion thereof (slurry), and the obtained solution of the polyamic acid (A3), in the same way as in the method for producing the fine particle powder having an optical anisotropy (B) which is surface-treated with the polyamic acid (A3) as described above.

A dispersion obtained by dispersing the isolated fine particle powder having an optical anisotropy (B) which is surface-treated with the polyamic acid (A3) as described above in a solvent will also be the fine particle dispersion of the present invention of the fine particle having an optical anisotropy (B) which comprises the polyamic acid (A3) as the dispersant. The method for dispersing the fine particle having an optical anisotropy (B) in the solvent is not particularly limited, and any known dispersion method may be suitably applied.

The content of the polyamic acid in the fine particle dispersion of the present invention is preferably, but not limited to, 0.5 parts by weight to 50 parts by weight, more preferably 1 parts by weight to 30 parts by weight, more preferably 3 parts by weight to 25 parts by weight, particularly preferably 5 parts by weight to 15 parts by weight, relative to 100 parts by weight of the fine particle having an optical anisotropy (B).

Next, the polyimide precursor composition of the present invention comprising the polyimide precursor (A1) as described above and the fine particle having an optical anisotropy (B) as described above, and the polyimide composition of the present invention comprising the polyimide (A2) as described above and the fine particle having an optical anisotropy (B) as described above will be described below in detail.

<Polyimide precursor composition, and Polyimide composition>

The polyimide precursor composition of the present invention is the one comprising at least one polyimide precursor (A1) and at least one fine particle having an optical anisotropy (B). The polyimide composition of the present invention is the one comprising at least one polyimide (A2) and at least one fine particle having an optical anisotropy (B). The retardation in the thickness direction and in the in-plane direction may be reduced by adding a fine particle having an optical anisotropy (B) to a polyimide, while maintaining the properties inherent in the polyimide.

The content of the fine particle having an optical anisotropy (B) in the polyimide precursor composition of the present invention and the polyimide composition of the present invention is preferably, but not limited to, 1 parts by weight or more, more preferably 5 parts by weight or more, more preferably 10 parts by weight or more, particularly preferably 20 parts by weight or more, relative to 100 parts by weight of the polymer solid content of the polyimide precursor (A1) or the polyimide (A2). When the content is within the range, the retardation of the obtained polyimide composition in the thickness direction and in the in-plane direction may be sufficiently reduced. Meanwhile, the content of the fine particle having an optical anisotropy (B) in the polyimide precursor composition of the present invention and the polyimide composition of the present invention is preferably, but not limited to, 60 parts by weight or less, more preferably 40 parts by weight or less, more preferably 20 parts by weight or less, relative to 100 parts by weight of the polymer solid content of the polyimide precursor (A1) or the polyimide (A2). When the content is within the range, the obtained polyimide composition may have excellent properties such as heat resistance and transparency.

The content of the fine particle having an optical anisotropy (B) in the polyimide precursor composition of the present invention and the polyimide composition of the present invention may be determined by a known method of composition analysis. The content may also be determined from the amount of the fine particle having an optical anisotropy (B) added in the production process.

The polyimide precursor composition of the present invention usually comprises a polyimide precursor (A1), a fine particle having an optical anisotropy (B), and a solvent (C). In one embodiment, the polyimide composition of the present invention comprises a polyimide (A2), a fine particle having an optical anisotropy (B), and a solvent (C). In this embodiment, it is preferred that the polyimide (A2) is soluble in the solvent (C). The polyimide precursor composition or the polyimide composition comprising a polyimide precursor (A1) or a polyimide (A2), a fine particle having an optical anisotropy (B), and a solvent (C) is also referred to as “the varnish of the present invention”.

As the solvent (C) used for the varnish of the present invention comprising a polyimide precursor (the polyimide precursor composition of the present invention), any solvent may be used without any trouble on the condition that the polyimide precursor can be dissolved in the solvent, and the structure thereof is not particularly limited. Meanwhile, as the solvent (C) used for the varnish of the present invention comprising a polyimide (varnish of polyimide), any solvent may be used without any trouble on the condition that the polyimide can be dissolved in the solvent, and the structure thereof is not particularly limited. As the solvent, water, or amide solvents such as N,N-dimethylformamide, N,N-dimethylacetamide and N-methyl-2-pyrrolidone; cyclic ester solvents such as γ-butyrolactone, γ-valerolactone, δ-valerolactone, γ-caprolactone, ε-caprolactone and α-methyl-γ-butyrolactone; carbonate solvents such as ethylene carbonate and propylene carbonate; glycol solvents such as triethylene glycol; phenol solvents such as m-cresol, p-cresol, 3-chlorophenol and 4-chlorophenol; acetophenone, 1,3-dimethyl-2-imidazolidinone, sulfolane, dimethylsulfoxide, and the like may be preferably employed. In addition, other common organic solvents, namely, phenol, o-cresol, butyl acetate, ethyl acetate, isobutyl acetate, propyleneglycol methyl acetate, ethyl cellosolve, butyl cellosolve, 2-methyl cellosolve acetate, ethyl cellosolve acetate, butyl cellosolve acetate, tetrahydrofuran, dimethoxyethane, diethoxyethane, dibutyl ether, diethylene glycol dimethyl ether, methyl isobutyl ketone, diisobutyl ketone, cyclopentanone, cyclohexanone, methyl ethyl ketone, acetone, butanol, ethanol, xylene, toluene, chlorobenzene, turpentine, mineral spirits, petroleum naphtha-based solvents, and the like may be used. Additionally, these may be used in combination of a plurality of types. The solvent used in the preparation of the polyimide precursor (A1) or the polyimide (A2), and the solvent (dispersion medium) of the dispersion of the fine particle having an optical anisotropy (B) may be used, as it is, as the solvent of the varnish of the present invention.

In the varnish of the present invention, it is preferred that the total amount of the tetracarboxylic acid component and the diamine component is 5 mass % or more, preferably 10 mass % or more, more preferably 15 mass % or more, relative to the total amount of the solvent, the tetracarboxylic acid component and the diamine component. Additionally, it is generally preferred that the total amount of the tetracarboxylic acid component and the diamine component is 60 mass % or less, preferably 50 mass % or less, relative to the total amount of the solvent, the tetracarboxylic acid component and the diamine component. When the concentration (total amount of the tetracarboxylic acid component and the diamine component), which is approximate to the concentration of the solid content based on the polyimide precursor or the polyimide, is too low, it may be difficult to control the thickness of the obtained polyimide film in the production of the polyimide film, for example.

In the varnish of the polyimide precursor of the present invention, the logarithmic viscosity of the polyimide precursor in a N,N-dimethylacetamide solution at a concentration of 0.5 g/dL at 30° C. may be preferably 0.2 dL/g or more, more preferably 0.3 dL/g or more, particularly preferably 0.4 dL/g or more, although the logarithmic viscosity is not limited thereto. When the logarithmic viscosity is 0.2 dL/g or more, the molecular weight of the polyimide precursor is high, and therefore the obtained polyimide may have excellent mechanical strength and heat resistance.

In the varnish of the polyimide of the present invention, the logarithmic viscosity of the polyimide in a N,N-dimethylacetamide solution at a concentration of 0.5 g/dL at 30° C. may be preferably 0.2 dL/g or more, more preferably 0.4 dL/g or more, particularly preferably 0.5 dL/g or more, although the logarithmic viscosity is not limited thereto. When the logarithmic viscosity is 0.2 dL/g or more, the obtained polyimide may have excellent mechanical strength and heat resistance.

Although the viscosity (rotational viscosity) of the varnish of the present invention is not limited thereto, the rotational viscosity, which is measured with an E-type rotational viscometer at a temperature of 25° C. and at a shearing speed of 20 sec⁻¹, may be preferably 0.01 to 1000 Pa·sec, more preferably 0.1 to 100 Pa·sec. In addition, thixotropy may be imparted, as necessary. When the viscosity is within the above-mentioned range, the varnish is easy to handle during the coating or the film formation, and the varnish is less repelled and has excellent leveling property, and therefore a good film may be obtained.

The varnish comprising a polyimide precursor of the present invention may comprise a chemical imidizing agent (an acid anhydride such as acetic anhydride, and an amine compound such as pyridine and isoquinoline), an anti-oxidizing agent, a filler (including an inorganic particle such as silica), a dye, a pigment, a coupling agent such as a silane coupling agent, a primer, a flame retardant, a defoaming agent, a leveling agent, a rheology control agent (flow-promoting agent), a releasing agent, and the like, as necessary.

The varnish comprising a polyimide of the present invention may comprise an anti-oxidizing agent, a filler (including an inorganic particle such as silica), a dye, a pigment, a coupling agent such as a silane coupling agent, a primer, a flame retardant, a defoaming agent, a leveling agent, a rheology control agent (flow-promoting agent), a releasing agent, and the like, as necessary.

The polyimide precursor composition of the present invention which is the varnish of the present invention may be prepared by adding a fine particle having an optical anisotropy (B) or a dispersion of a fine particle having an optical anisotropy (B) to a polyimide precursor solution or solution composition obtained by the method for producing the polyimide precursor (A1) as described above, and mixing them. The polyimide precursor composition of the present invention may also be preferably prepared by adding a tetracarboxylic acid component (a tetracarboxylic dianhydride, or the like) and a diamine component to a solvent, and further adding a fine particle having an optical anisotropy (B) or a dispersion of a fine particle having an optical anisotropy (B) thereto, and mixing them to disperse the fine particle having an optical anisotropy (B) in the solvent, and then reacting the tetracarboxylic acid component and the diamine component in the presence of the fine particle having an optical anisotropy (B), because the dispersibility of the fine particle having an optical anisotropy (B) is good, although the production method is not limited thereto. In addition, the fine particle having an optical anisotropy (B) to be used is preferably the one which is surface-treated with a surface treatment agent such as a polyamic acid comprising a repeating unit represented by the chemical formula (8), for example. Additionally, the solvent may be removed therefrom or added thereto, or a desired component other than the fine particle having an optical anisotropy (B) may be added thereto, as necessary.

The varnish of the present invention comprising a polyimide (composition comprising a polyimide (A2), a fine particle having an optical anisotropy (B), and a solvent) may be prepared from the polyimide precursor composition of the present invention by imidizing the polyimide precursor in the varnish (i.e., subjecting the polyimide precursor to the dehydration/ring closure reaction). The imidization method is not particularly limited, and any known thermal imidization or chemical imidization method may be suitably applied. The varnish of the present invention comprising a polyimide may also be prepared by reacting a tetracarboxylic acid component (a tetracarboxylic dianhydride, or the like) and a diamine component in a solvent to obtain a polyimide solution or solution composition, and then adding a fine particle having an optical anisotropy (B) or a dispersion of a fine particle having an optical anisotropy (B) thereto, and mixing them. In this case, the fine particle having an optical anisotropy (B) may be the one which is surface-treated with a surface treatment agent such as a polyamic acid comprising a repeating unit represented by the chemical formula (8), for example. Additionally, the solvent may be removed therefrom or added thereto, or a desired component other than the fine particle having an optical anisotropy (B) may be added thereto, as necessary.

As for the method for producing the varnish of the present invention comprising the polyimide (A2), in the case of thermal imidization, a solution or solution composition comprising the polyimide (A2) may be obtained by stirring a solution or solution composition of the polyimide precursor (A1), which is obtained by the method as described above, at 80° C. to 230° C., preferably 120° C. to 200° C., for 1 hour to 24 hours, for example, although the production method is not limited thereto. The imidization may be performed while bubbling, or adding an azeotropic solvent such as toluene thereto so as to remove by-products such as water which is formed with the imidization. In addition, a polyimide solution may also be obtained by dropping the obtained polyimide solution into a poor solvent such as water and methanol, and re-precipitating and drying the polyimide, and then dissolving the polyimide in a solvent in which the polyimide is soluble again, and the varnish of the present invention comprising a polyimide may also be prepared using the polyimide solution.

The solvent (dispersion medium) of the dispersion of the fine particle having an optical anisotropy (B) to be used in the production of the polyimide precursor composition of the present invention, which is the varnish of the present invention, or the varnish of the present invention comprising a polyimide is not particularly limited, on the condition that the polyimide precursor or the polyimide can be dissolved in the solvent, and any solvent may be used without any trouble. Examples of the solvent of the dispersion of the fine particle having an optical anisotropy (B) include the same as the solvent used in the production of the polyimide precursor (A1) as described above. The solvent of the dispersion of the fine particle having an optical anisotropy (B) may be the same as, or different from the solvent of the solution of the polyimide precursor or the solution of the polyimide. The solvent may be used in combination of a plurality of types.

The dispersion of the fine particle having an optical anisotropy (B) may comprise one or more dispersants in order to efficiently disperse the fine particle having an optical anisotropy (B) in the solvent, thereby forming a stable fine particle dispersion.

As described above, the dispersant is preferably, but not limited to, the one having a carboxylic acid as the functional group, particularly preferably a polyamic acid. As the polyamic acid, the polyamic acid comprising a repeating unit represented by the chemical formula (8) presented as the surface treatment agent for the fine particle having an optical anisotropy (B) is preferred. In other words, a fine particle dispersion comprising a polyamic acid (A3) comprising a repeating unit represented by the chemical formula (8), a fine particle having an optical anisotropy (B), and a solvent (the fine particle dispersion of the present invention) may be suitably used as the dispersion of the fine particle having an optical anisotropy (B).

When the dispersion of the fine particle having an optical anisotropy (B) comprises the polyamic acid as the dispersant, the content of the polyamic acid is preferably, but not limited to, 0.5 parts by weight to 50 parts by weight, more preferably 1 parts by weight to 30 parts by weight, more preferably 3 parts by weight to 25 parts by weight, relative to 100 parts by weight of the fine particle having an optical anisotropy (B). The polyamic acid as the dispersant is also converted to a polyimide, and therefore the content of the fine particle having an optical anisotropy (B) in the polyimide composition as described above may be calculated, provided that the polyimide converted from the polyamic acid as the dispersant is included in the polyimide (A2).

In addition, the surface treatment agent for the needle-shaped strontium carbonate fine powder described in JP-A-2014-80360, that is, a polycarboxylic acid having a polyoxyalkylene group as the side-chain, or an anhydride thereof, and an amine having a polyoxyalkylene group and a hydrocarbon group may also be suitably used as the dispersant for the dispersion of the fine particle having an optical anisotropy (B), as described above. In the present invention, the amount of the polycarboxylic acid, or the anhydride thereof to be added, and the amount of the amine to be added are preferably the amounts described in JP-A-2014-80360.

In one embodiment of the present invention, it is preferred, in view of the transparency of the obtained polyimide composition, or the like, that a commonly-used dispersant is not used, although other common dispersants may be used. The amount of the commonly-used dispersant other than the polyamic acid, or the like to be added is usually preferably, but not limited to, 10 parts by weight or less relative to 100 parts by weight of the fine particle having an optical anisotropy (B).

The method for dispersing the fine particle having an optical anisotropy (B) in the solvent is not particularly limited, and any known dispersion method may be suitably applied. For the dispersion, a ball mill, a jet mill, a bead mill, an impeller disperser, a thin-film spinning mixer, or the like may be preferably used, for example. The method for mixing the solution of the polyimide precursor or the solution of the polyimide and the dispersion of the fine particle having an optical anisotropy (B) is also not particularly limited, and any known mixing method may be suitably applied.

The polyimide composition of the present invention is the one comprising a polyimide (A2) and a fine particle having an optical anisotropy (B), and may be obtained from the polyimide precursor composition of the present invention comprising a polyimide precursor (A1) and a fine particle having an optical anisotropy (B). More specifically, the polyimide composition of the present invention may be obtained by heating the polyimide precursor composition of the present invention, or the like, to imidize the polyimide precursor (i.e., subject the polyimide precursor to the dehydration/ring closure reaction). The imidization method is not particularly limited, and any known thermal imidization or chemical imidization method may be suitably applied.

For example, the polyimide composition such as a polyimide film may be suitably produced by

flow-casting the polyimide precursor composition of the present invention (the varnish of the polyimide precursor) on a base, and then

heating the polyimide precursor composition on the base, for example, at a temperature of 100° C. to 500° C., preferably 200° C. to 500° C., more preferably about 250° C. to about 450° C., to remove the solvent therefrom and imidize the polyimide precursor.

The heating profile is not particularly limited, and may be appropriately selected.

The polyimide composition such as a polyimide film may also be suitably produced by

flow-casting the polyimide precursor composition of the present invention (the varnish of the polyimide precursor) on a base,

drying the composition preferably at a temperature of 180° C. or lower, to form a film of the polyimide precursor composition on the base,

peeling the obtained film of the polyimide precursor composition from the base, and then

heating the film in a state where the edges of the film are fixed, or the edges of the film are not fixed, for example, at a temperature of 100° C. to 500° C., preferably 200° C. to 500° C., more preferably about 250° C. to about 450° C., to imidize the polyimide precursor.

In addition, the polyimide composition of the present invention such as a polyimide film (the polyimide composition which does not comprise a solvent) may also be obtained by heating the varnish of the present invention which comprises a polyimide (the composition comprising a polyimide (A2), a fine particle having an optical anisotropy (B), and a solvent), or the like, to remove the solvent therefrom.

For example, the polyimide composition such as a polyimide film may be suitably produced by

flow-casting the varnish of the present invention which comprises a polyimide on a base, and then

heating the varnish, for example, at a temperature of 80° C. to 500° C., preferably 100° C. to 500° C., more preferably about 150° C. to about 450° C., to remove the solvent therefrom.

In this case, the heating profile is not particularly limited, and may be appropriately selected.

One more specific example of the method for producing the polyimide composition of the present invention (a polyimide film/base laminate, or a polyimide film) will be described later.

As described above, according to the present invention, not only the retardation in the in-plane direction but also the retardation in the thickness direction may be easily reduced by adding a fine particle having an optical anisotropy to a varnish (a polyimide precursor solution composition, a polyimide solution composition) as in the above-described production method, without aligning the needle- or rod-shaped fine particle having an optical anisotropy such as strontium carbonate in one direction by hot-stretching a film of a polyimide composition, or by melting a polyimide composition and injection-molding or extrusion-molding the polyimide composition, or the like, that is, without a special treatment for the alignment of the fine particle.

Preferred examples of the form of the polyimide composition of the present invention (a polyimide which contains a fine particle having an optical anisotropy) include a film, a laminate of a polyimide film and another substrate, a coating film, a powder, a bead, a molded article, and a foamed article.

The polyimide composition obtained from the polyimide precursor composition of the present invention, and the polyimide composition of the present invention may have preferably, but not limited to, a coefficient of linear thermal expansion from 100° C. to 250° C. of 60 ppm/K or less, more preferably 50 ppm/K or less, when the polyimide is formed into a film having a thickness of 5 μm to 250 μm, preferably a film having a thickness of 10 μm. When the coefficient of linear thermal expansion is great, the difference in coefficient of linear thermal expansion between the polyimide and a conductive material such as a metal is great, and therefore a trouble such as an increase in warpage may occur during the formation of a circuit board.

The polyimide composition obtained from the polyimide precursor composition of the present invention, and the polyimide composition of the present invention may have preferably, but not limited to, a total light transmittance (average light transmittance at wavelengths of 380 nm to 780 nm) of 68% or more, more preferably 70% or more, more preferably 75% or more, particularly preferably 80% or more, in the form of a film having a thickness of 5 μm to 250 μm, preferably a film having a thickness of 10 μm. When the total light transmittance is low, the light source must be bright, and therefore a problem of more energy required, or the like may arise in the case where the polyimide is used in display application, or the like.

The polyimide composition obtained from the polyimide precursor composition of the present invention, and the polyimide composition of the present invention may have preferably, but not limited to, a 5% weight loss temperature, which is the index of the heat resistance of the polyimide film, of 400° C. or more, more preferably 430° C. or more, more preferably 450° C. or more. In the case where a gas barrier film, or the like is formed on the polyimide for the formation of a transistor on the polyimide, or the like, swelling may occur between the polyimide and the barrier film due to outgassing associated with the decomposition of the polyimide when the heat resistance is low.

The polyimide composition obtained from the polyimide precursor composition of the present invention, and the polyimide composition of the present invention may have preferably, but not limited to, a retardation in the thickness direction of the polyimide film of 1000 nm or less, more preferably 800 nm or less, more preferably 700 nm or less, particularly preferably 680 nm or less, in the form of a film having a thickness of 5 μm to 250 μm, preferably a film having a thickness of 10 μm. In an application where a particularly high performance is required among optical films, it may be preferred that the retardation in the thickness direction of the polyimide film is preferably 75 nm or less. When the retardation in the thickness direction is great, a problem that the color of the transmitted light is not correctly displayed, or color is blurred, or a viewing angle is narrowed may arise. The retardation in the in-plane direction of the polyimide film may be preferably 100 nm or less, more preferably 50 nm or less, more preferably 10 nm or less, more preferably 5 nm or less. In an application where a particularly high performance is required among optical films, it may be preferred that the retardation in the in-plane direction of the polyimide film is preferably 4 nm or less, more preferably 3 nm or less.

As for the film formed of the polyimide composition obtained from the polyimide precursor composition of the present invention, or the polyimide composition of the present invention, the thickness of the film is preferably 0.1 μm to 250 μm, more preferably 1 μm to 150 μm, more preferably 1 μm to 50 μm, particularly preferably 1 μm to 30 μm, although it varies depending on the intended use. When the polyimide film is too thick, the light transmittance may be low in the case where the polyimide film is used in an application where light passes through the polyimide film.

The polyimide composition obtained from the polyimide precursor composition of the present invention, and the polyimide composition of the present invention may be suitably used, for example, in the applications of transparent substrate for display, transparent substrate for touch panel, or substrate for solar battery, and in the applications of substrates for other optical devices and semiconductor devices.

One example of a method for producing a polyimide film/base laminate, or a polyimide film with the use of the polyimide precursor composition of the present invention (the varnish of the polyimide precursor) will be described below. However, the production method is not limited to the method as described below.

The varnish of the present invention (polyimide precursor composition) is flow-cast on a base, for example, made of ceramic (glass, silicon, alumina, or the like), metal (copper, aluminum, stainless steel, or the like), heat-resistant plastic film (polyimide film, or the like), or the like, and dried at a temperature of 20° C. to 180° C., preferably 20° C. to 150° C., by the use of hot air or infrared ray in a vacuum, in an inert gas such as nitrogen, or in air. And then, the obtained polyimide precursor film is heated and imidized, for example, at a temperature of 200° C. to 500° C., more preferably about 250° C. to about 450° C., by the use of hot air or infrared ray in a vacuum, in an inert gas such as nitrogen, or in air, wherein the polyimide precursor film is on the base, or alternatively, the polyimide precursor film is peeled from the base and fixed at the film edges, to produce a polyimide film/base laminate, or a polyimide film. The thermal imidization is preferably performed in a vacuum or in an inert gas so as to prevent oxidation and degradation of the obtained polyimide film. The thermal imidization may be performed in air if the thermal imidization temperature is not too high. At this point, the thickness of the polyimide film (the polyimide film layer, in the case of a polyimide film/base laminate) is preferably 1 μm to 250 μm, more preferably 1 μm to 150 μm, in view of the transportability in the subsequent steps.

The imidization reaction of the polyimide precursor may also be performed by chemical treatment in which the polyimide precursor is immersed in a solution containing a dehydrating/cyclizing agent such as acetic anhydride in the presence of a tertiary amine such as pyridine and triethylamine, instead of the thermal imidization by heat treatment as described above. Alternatively, a partially-imidized polyimide precursor may be prepared by adding the dehydrating/cyclizing agent to the varnish (polyimide precursor composition) in advance and stirring the varnish, and then flow-casting the varnish on a base and drying it, and a polyimide film/base laminate, or a polyimide film may be obtained by further subjecting this partially-imidized polyimide precursor to heat treatment as described above.

A flexible conductive substrate may be obtained by forming a conductive layer on one surface or both surfaces of the polyimide film/base laminate or the polyimide film thus obtained.

A flexible conductive substrate may be obtained by the following methods, for example. As for the first method, the polyimide film is not peeled from the base in the polyimide film/base laminate, and a conductive layer of a conductive material (metal or metal oxide, conductive organic material, conductive carbon, or the like) is formed on the surface of the polyimide film by sputtering, vapor deposition, printing, or the like, to provide a conductive laminate which is a conductive layer/polyimide film/base laminate. And then, as necessary, the conductive layer/polyimide film laminate is peeled from the base, to provide a transparent and flexible conductive substrate which consists of a conductive layer/polyimide film laminate.

As for the second method, the polyimide film is peeled from the base in the polyimide film/base laminate to obtain the polyimide film, and then a conductive layer of a conductive material (metal or metal oxide, conductive organic material, conductive carbon, or the like) is formed on the surface of the polyimide film in the same way as in the first method, to provide a transparent and flexible conductive substrate which consists of a conductive layer/polyimide film laminate, or a conductive layer/polyimide film/conductive layer laminate.

In the first and the second methods, a gas barrier layer against water vapor, oxygen, or the like, and an inorganic layer such as a light-controlling layer may be formed on the surface of the polyimide film by sputtering, vapor deposition, gel-sol process, or the like, as necessary, before the conductive layer is formed. The gas barrier layer herein is not particularly limited, on the condition that it is a layer having a lower permeability to oxygen and/or water vapor, or the like than the polyimide film, for example, and is an inorganic layer, an organic layer, or an inorganic/organic hybrid layer, for example, and is preferably a film of an inorganic oxide such as silicon oxide, aluminum oxide, silicon carbide, silicon oxide carbide, silicon carbide nitride, silicon nitride, and silicon nitride oxide. The gas barrier layer may be composed of only one composition, or may be a film in which two or more compositions are mixed.

In addition, a circuit may be suitably formed on the conductive layer by photolithography process, various printing processes, ink-jet process, or the like.

The substrate of the present invention thus obtained has a circuit of a conductive layer on a surface of a polyimide film formed of the polyimide composition obtained from the polyimide precursor composition of the present invention, or the polyimide composition of the present invention, optionally with a gas barrier layer or an inorganic layer therebetween, as necessary. The substrate is flexible, and may be suitably used, for example, as a substrate for a display, a touch panel, or a solar battery.

More specifically, a flexible thin-film transistor is produced by further forming a transistor (Examples of the material used herein for semiconductors include amorphous silicon, low-temperature polysilicon, oxide semiconductors such as ZnO, SnO and IGZO, and organic semiconductors) on the substrate by vapor deposition, various printing processes, ink-jet process, or the like, and is suitably used as a liquid crystal device for display device, an EL device, or a photoelectric device.

A polyimide film laminate comprising a polyimide film and at least one glass layer may be obtained in the production process when a glass is used as the base in the production method as described above. In addition, a polyimide film laminate comprising a polyimide film and at least one gas barrier layer (for example, an inorganic layer, an organic layer, or an inorganic/organic hybrid layer, which has a lower permeability to oxygen than the polyimide film) may be obtained in the production process when a gas barrier layer is formed. These laminates are one form of the polyimide film laminate of the present invention. In addition, a laminate in which a thin-film transistor (an inorganic transistor, or an organic transistor) is formed, that is, a polyimide film laminate comprising a polyimide film and at least one thin-film transistor, and a laminate in which a conductive layer is formed, that is, a polyimide film laminate comprising a polyimide film and at least one conductive layer are also one form of the polyimide film laminate of the present invention.

The polyimide composition obtained from the polyimide precursor composition of the present invention, and the polyimide composition of the present invention also may be suitably used, for example, for display devices such as an organic EL display, a liquid crystal display, an electrophoretic display, a plasma display, a plasma addressed liquid crystal display, an inorganic EL display, a field emission display, or a surface conduction display, sensor devices such as a touch panel, photoelectric conversion devices such as a solar battery, optical devices such as an optical waveguide, and other semiconductor devices.

### EXAMPLES

The present invention will be further described below with reference to Examples and Comparative Examples. However, the present invention is not limited to the Examples as described below.

In each of the Examples as described below, the evaluations were conducted by the following methods.

### <Evaluation of Polyimide Film>

[Retardation in the in-Plane Direction (Rₑ) and Retardation in the Thickness Direction (Rₜₕ) of the Film]

The polyimide film having a thickness of 10 μm was used as a test piece, and the Rₑ and the Rₜₕ were measured using a retardation measuring apparatus (KOBRA-WR) made by Oji Scientific Instruments Co., Ltd. The measurement of the retardation of the film was conducted at an Rₜₕ incidence angle of 40°. The retardation in the thickness direction of the film having a thickness of 10 μm was determined from the obtained retardation.

[Total Light Transmittance]

The light transmittance at the total light transmittance (average transmittance at 380 nm to 780 nm) of the polyimide film having a thickness of 10 μm was measured using a UV-visible spectrophotometer V-650DS (made by JASCO Corporation).

[Tensile Modulus of Elasticity, Elongation at Break, Strength at Break]

The polyimide film was cut to the dumbbell shape of IEC-540(S) standard, which was used as a test piece (width: 4 mm), and the initial tensile modulus of elasticity, the elongation at break, and the strength at break were measured at a distance between chucks of 30 mm and a tensile speed of 2 mm/min using a TENSILON made by Orientec Co., Ltd.

[Coefficient of Linear Thermal Expansion (CTE)]

The polyimide film was cut to a rectangle having a width of 4 mm, which was used as a test piece, and the test piece was heated to 500° C. at a distance between chucks of 15 mm, a load of 2 g and a temperature-increasing rate of 20° C./min using a TMA/SS6100 (made by SII Nanotechnology Inc.). The coefficient of linear thermal expansion from 100° C. to 250° C. was determined from the obtained TMA curve.

[5% Weight Loss Temperature]

The polyimide film was used as a test piece, and the test piece was heated from 25° C. to 600° C. at a temperature-increasing rate of 10° C./min in a flow of nitrogen using a thermogravimetric measuring apparatus (Q5000IR) made by TA Instruments Inc. The 5% weight loss temperature was determined from the obtained weight curve.

The abbreviations, purities, etc. of the raw materials used in each of the Examples as described below are as follows.

[Diamine component]

BAPB: 4,4′-bis(4-aminophenoxy)biphenyl [purity: 99.93% (HPLC analysis)]
PPD: p-phenylenediamine [purity: 99.9% (GC analysis)]
DABAN: 4,4′-diaminobenzanilide [purity: 99.90% (GC analysis)]
1,4-tra-DACH: trans-1,4-diaminocyclohexane [purity: 99.1% (GC analysis)]
4,4′-ODA: 4,4′-oxydianiline [purity: 99.9% (GC analysis)]
TFMB: 2,2′-bis(trifluoromethyl)benzidine [purity: 99.83% (GC analysis)]
m-TD: 2,2′-dimethyl-4,4′-diaminobiphenyl [purity: 99.85% (GC analysis)]

[Tetracarboxylic Acid Component]

CpODA: norbornane-2-spiro-α-cyclopentanone-α′-spiro-2″-norbornane-5,5″,6,6″-tetracarboxylic dianhydride
s-BPDA: 3,3′,4,4′-biphenyltetracarboxylic dianhydride [purity: 99.9% (H-NMR analysis)]
a-BPDA: 2,3,3′,4′-biphenyltetracarboxylic dianhydride [purity: 99.6% (H-NMR analysis)]
H-PMDA: 1R,2S,4S,5R-cyclohexane tetracarboxylic dianhydride [purity: 99.9% (GC analysis)]
6FDA: 4,4′-(2,2-hexafluoroisopropylene)diphthalic dianhydride [purity: 99.77% (H-NMR analysis)]
CBDA: 1,2,3,4-cyclobutane tetracarboxylic dianhydride [purity: 99.9% (GC analysis)]

[Solvent]

NMP: N-methyl-2-pyrrolidone
Water: pure water

[Strontium Carbonate Dispersion]

Strontium carbonate dispersion (1): A dispersion (solvent: NMP) using the strontium carbonate described in JP-A-2014-80360 was provided as the strontium carbonate dispersion (1). The dispersion (1) had a strontium carbonate content of 10 mass %, an average long diameter length of 36.7 nm, an average aspect ratio of 2.3, and a content of particle having a long diameter length of 200 nm or more of 0%.
Strontium carbonate dispersion (2): Strontium carbonate was dispersed in NMP by a known dispersion method without using a dispersant. The dispersion (2) had a strontium carbonate content of 10 mass %, an average long diameter length of 36.7 nm, an average aspect ratio of 2.3, and a content of particle having a long diameter length of 200 nm or more of 0%.
Strontium carbonate dispersion (3): A dispersion (solvent: water) using the strontium carbonate described in JP-A-2014-80360 was provided as the strontium carbonate dispersion (3). The dispersion (3) (aqueous slurry) had a strontium carbonate content of 5.5 mass %, an average long diameter length of 31.7 nm, an average aspect ratio of 2.4, and a content of particle having a long diameter length of 200 nm or more of 0%.

The average long diameter length, the average aspect ratio, and the content of particle having a long diameter length of 200 nm or more (based on the number of particles) of the strontium carbonate were determined by image analysis from the SEM image.

### Example S-1

9.09 g (0.04 mol) of DABAN, 5.41 g (0.05 mol) of PPD and 3.68 g (0.01 mol) of BAPB were placed in a reaction vessel, which was purged with nitrogen gas, and 509.58 g of N-methyl-2-pyrrolidone was added thereto such that the total mass of the charged monomers (total mass of the diamine component and the carboxylic acid component) was 10 mass %, and then the mixture was stirred at room temperature for 1 hour. 38.44 g (0.10 mol) of CpODA was gradually added to the resulting solution. The mixture was stirred at room temperature for 12 hours, to obtain a homogeneous and viscous solution of a polyimide precursor (polyamic acid). 10 g of the obtained polyimide precursor solution and 40 g of the strontium carbonate dispersion (2) were treated for 90 minutes using a planetary ball mill (premium-line P-7) from Fritsch and using 50 g of ZrO₂ with 0.3 mm, to obtain a strontium carbonate dispersion (4).

### Example S-21

11.42 g (0.100 mol) of 1,4-tra-DACH was placed in a reaction vessel, which was purged with nitrogen gas, and 231.37 g of water was added thereto such that the total mass of the charged monomers (total mass of the diamine component and the carboxylic acid component) was 15 mass %, and then the mixture was stirred at room temperature for 1 hour. 21.15 g (0.220 mol) of 1,2-dimethylimidazole was added to the resulting solution, and then the mixture was stirred at room temperature for 1 hour. 28.67 g (0.0975 mol) of s-BPDA and 0.74 g (0.0025 mol) of a-BPDA were gradually added to the resulting solution. The mixture was stirred at room temperature for 12 hours, to obtain a homogeneous and viscous solution of a polyimide precursor (polyamic acid). 300 g of the strontium carbonate dispersion (3) was dispersed using 15 g of the obtained polyimide precursor solution as a dispersant, to obtain a strontium carbonate dispersion (5) (particle diameter D₅₀ 79 nm, D₉₀ 130 nm, measured by a laser diffraction particle size distribution measuring apparatus).

The structural formulas of the tetracarboxylic acid components used in Examples and Comparative Examples, and the diamine components used in Examples and Comparative Examples are shown in Table 1-1, and Table 1-2, respectively.

TABLE 1-1
Tetracarboxylic dianhydride

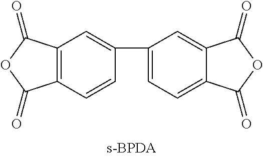 [SMILES: O=C1OC(=O)c2cc(-c3ccc4c(c3)C(=O)OC4=O)ccc21]

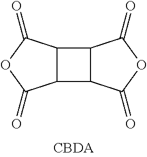 [SMILES: O=C1OC(=O)C2C1C1C(=O)OC(=O)C21]

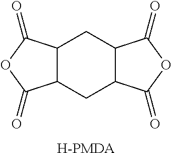

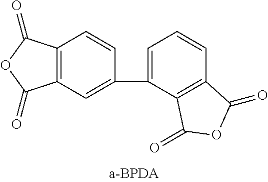 [SMILES: O=C1OC(=O)c2cc(-c3cccc4c3C(=O)OC4=O)ccc21]

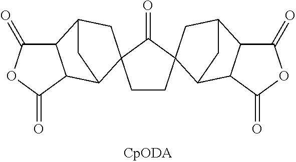 [SMILES: O=C1OC(=O)C2C1C1CC2C2(CCC3(CC4CC3C3C(=O)OC(=O)C43)C2=O)C1]

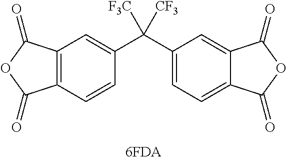 [SMILES: O=C1OC(=O)c2cc(C(c3ccc4c(c3)C(=O)OC4=O)(C(F)(F)F)C(F)(F)F)ccc21]

TABLE 1-2
Diamine

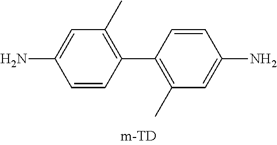 [SMILES: Cc1cc(N)ccc1-c1ccc(N)cc1C]

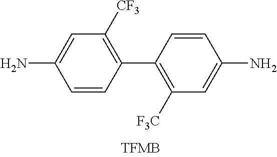 [SMILES: Nc1ccc(-c2ccc(N)cc2C(F)(F)F)c(C(F)(F)F)c1]

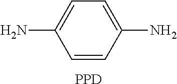

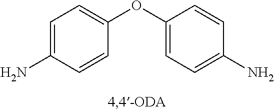 [SMILES: Nc1ccc(Oc2ccc(N)cc2)cc1]

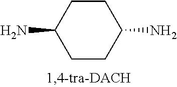

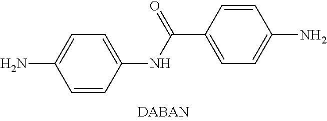 [SMILES: Nc1ccc(NC(=O)c2ccc(N)cc2)cc1]

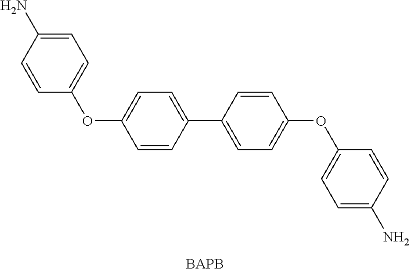 [SMILES: Nc1ccc(Oc2ccc(-c3ccc(Oc4ccc(N)cc4)cc3)cc2)cc1]

### Example 1

0.91 g (0.004 mol) of DABAN, 0.54 g (0.005 mol) of PPD and 0.37 g (0.001 mol) of BAPB were placed in a reaction vessel, which was purged with nitrogen gas, and 24.13 g of N-methyl-2-pyrrolidone was added thereto such that the total mass of the charged monomers (total mass of the diamine component and the carboxylic acid component) was 19 mass %, and then the mixture was stirred at room temperature for 1 hour. 3.84 g (0.010 mol) of CpODA was gradually added to the resulting solution. The mixture was stirred at room temperature for 12 hours, to obtain a homogeneous and viscous polyimide precursor solution. 5.66 g of the strontium carbonate dispersion (1) was added to the obtained polyimide precursor solution, and then the mixture was stirred at room temperature for 1 hour.

The polyimide precursor solution was applied on a glass substrate, and then the polyimide precursor was thermally imidized by heating the polyimide precursor solution on the glass substrate from room temperature to 410° C. in a nitrogen atmosphere (oxygen concentration: 200 ppm or less), to obtain a colorless and transparent polyimide film/glass laminate. Subsequently, the obtained polyimide film/glass laminate was immersed in water, and then the polyimide film was peeled from the glass and dried, to obtain a polyimide film having a thickness of about 10 μm.

The results of the measurements of the properties of the polyimide film are shown in Table 2-1.

### Example 2

2.83 g of the strontium carbonate dispersion (1) and 25.08 g of N-methyl-2-pyrrolidone were placed in a reaction vessel, which was purged with nitrogen gas, and the mixture was stirred at room temperature for 1 hour. 0.91 g (0.004 mol) of DABAN, 0.54 g (0.005 mol) of PPD and 0.37 g (0.001 mol) of BAPB were added to the resulting solution, and then the mixture was stirred at room temperature for 1 hour. 3.84 g (0.010 mol) of CpODA was gradually added to the resulting solution. The mixture was stirred at room temperature for 12 hours, to obtain a viscous polyimide precursor solution.

The polyimide precursor solution was applied on a glass substrate, and then the polyimide precursor was thermally imidized by heating the polyimide precursor solution on the glass substrate from room temperature to 410° C. in a nitrogen atmosphere (oxygen concentration: 200 ppm or less), to obtain a colorless and transparent polyimide film/glass laminate. Subsequently, the obtained polyimide film/glass laminate was immersed in water, and then the polyimide film was peeled from the glass and dried, to obtain a polyimide film having a thickness of about 10 μm.

The results of the measurements of the properties of the polyimide film are shown in Table 2-1.

### Example 31

11.32 g of the strontium carbonate dispersion (1) and 17.44 g of N-methyl-2-pyrrolidone were placed in a reaction vessel, which was purged with nitrogen gas, and the mixture was stirred at room temperature for 1 hour. 0.91 g (0.004 mol) of DABAN, 0.54 g (0.005 mol) of PPD and 0.37 g (0.001 mol) of BAPB were added to the resulting solution, and then the mixture was stirred at room temperature for 1 hour. 3.84 g (0.010 mol) of CpODA was gradually added to the resulting solution. The mixture was stirred at room temperature for 12 hours, to obtain a viscous polyimide precursor solution.

The polyimide precursor solution was applied on a glass substrate, and then the polyimide precursor was thermally imidized by heating the polyimide precursor solution on the glass substrate from room temperature to 410° C. in a nitrogen atmosphere (oxygen concentration: 200 ppm or less), to obtain a colorless and transparent polyimide film/glass laminate. Subsequently, the obtained polyimide film/glass laminate was immersed in water, and then the polyimide film was peeled from the glass and dried, to obtain a polyimide film having a thickness of about 10 μm.

The results of the measurements of the properties of the polyimide film are shown in Table 2-1.

### Example 4

28.3 g of the strontium carbonate dispersion (1) and 2.16 g of N-methyl-2-pyrrolidone were placed in a reaction vessel, which was purged with nitrogen gas, and the mixture was stirred at room temperature for 1 hour. 0.91 g (0.004 mol) of DABAN, 0.54 g (0.005 mol) of PPD and 0.37 g (0.001 mol) of BAPB were added to the resulting solution, and then the mixture was stirred at room temperature for 1 hour. 3.84 g (0.010 mol) of CpODA was gradually added to the resulting solution. The mixture was stirred at room temperature for 12 hours, to obtain a viscous polyimide precursor solution.

The polyimide precursor solution was applied on a glass substrate, and then the polyimide precursor was thermally imidized by heating the polyimide precursor solution on the glass substrate from room temperature to 410° C. in a nitrogen atmosphere (oxygen concentration: 200 ppm or less), to obtain a colorless and transparent polyimide film/glass laminate. Subsequently, the obtained polyimide film/glass laminate was immersed in water, and then the polyimide film was peeled from the glass and dried, to obtain a polyimide film having a thickness of about 10 μm.

The results of the measurements of the properties of the polyimide film are shown in Table 2-1.

### Example 5

2.83 g of the strontium carbonate dispersion (2) and 25.08 g of N-methyl-2-pyrrolidone were placed in a reaction vessel, which was purged with nitrogen gas, and the mixture was stirred at room temperature for 1 hour. 0.91 g (0.004 mol) of DABAN, 0.54 g (0.005 mol) of PPD and 0.37 g (0.001 mol) of BAPB were added to the resulting solution, and then the mixture was stirred at room temperature for 1 hour. 3.84 g (0.010 mol) of CpODA was gradually added to the resulting solution. The mixture was stirred at room temperature for 12 hours, to obtain a viscous polyimide precursor solution.

The polyimide precursor solution was applied on a glass substrate, and then the polyimide precursor was thermally imidized by heating the polyimide precursor solution on the glass substrate from room temperature to 410° C. in a nitrogen atmosphere (oxygen concentration: 200 ppm or less), to obtain a colorless and transparent polyimide film/glass laminate. Subsequently, the obtained polyimide film/glass laminate was immersed in water, and then the polyimide film was peeled from the glass and dried, to obtain a polyimide film having a thickness of about 10 μm.

The results of the measurements of the properties of the polyimide film are shown in Table 2-1.

### Example 6

0.91 g (0.004 mol) of DABAN, 0.54 g (0.005 mol) of PPD and 0.37 g (0.001 mol) of BAPB were placed in a reaction vessel, which was purged with nitrogen gas, and 24.13 g of N-methyl-2-pyrrolidone was added thereto such that the total mass of the charged monomers (total mass of the diamine component and the carboxylic acid component) was 19 mass %, and then the mixture was stirred at room temperature for 1 hour. 3.84 g (0.010 mol) of CpODA was gradually added to the resulting solution. The mixture was stirred at room temperature for 12 hours, to obtain a homogeneous and viscous polyimide precursor solution. 7.08 g of the strontium carbonate dispersion (4) was added to the obtained polyimide precursor solution, and then the mixture was stirred at room temperature for 1 hour.

The polyimide precursor solution was applied on a glass substrate, and then the polyimide precursor was thermally imidized by heating the polyimide precursor solution on the glass substrate from room temperature to 410° C. in a nitrogen atmosphere (oxygen concentration: 200 ppm or less), to obtain a colorless and transparent polyimide film/glass laminate. Subsequently, the obtained polyimide film/glass laminate was immersed in water, and then the polyimide film was peeled from the glass and dried, to obtain a polyimide film having a thickness of about 10 μm.

The results of the measurements of the properties of the polyimide film are shown in Table 2-1.

### Example 7

7.08 g of the strontium carbonate dispersion (4) and 24.13 g of N-methyl-2-pyrrolidone were placed in a reaction vessel, which was purged with nitrogen gas, and the mixture was stirred at room temperature for 1 hour. 0.91 g (0.004 mol) of DABAN, 0.54 g (0.005 mol) of PPD and 0.37 g (0.001 mol) of BAPB were added to the resulting solution, and then the mixture was stirred at room temperature for 1 hour. 3.84 g (0.010 mol) of CpODA was gradually added to the resulting solution. The mixture was stirred at room temperature for 12 hours, to obtain a viscous polyimide precursor solution.

The polyimide precursor solution was applied on a glass substrate, and then the polyimide precursor was thermally imidized by heating the polyimide precursor solution on the glass substrate from room temperature to 410° C. in a nitrogen atmosphere (oxygen concentration: 200 ppm or less), to obtain a colorless and transparent polyimide film/glass laminate. Subsequently, the obtained polyimide film/glass laminate was immersed in water, and then the polyimide film was peeled from the glass and dried, to obtain a polyimide film having a thickness of about 10 μm.

The results of the measurements of the properties of the polyimide film are shown in Table 2-1.

### Comparative Example 1

0.91 g (0.004 mol) of DABAN, 0.54 g (0.005 mol) of PPD and 0.37 g (0.001 mol) of BAPB were placed in a reaction vessel, which was purged with nitrogen gas, and 24.13 g of N-methyl-2-pyrrolidone was added thereto such that the total mass of the charged monomers (total mass of the diamine component and the carboxylic acid component) was 19 mass %, and then the mixture was stirred at room temperature for 1 hour. 3.84 g (0.010 mol) of CpODA was gradually added to the resulting solution. The mixture was stirred at room temperature for 12 hours, to obtain a homogeneous and viscous polyimide precursor solution.

The polyimide precursor solution was applied on a glass substrate, and then the polyimide precursor was thermally imidized by heating the polyimide precursor solution on the glass substrate from room temperature to 410° C. in a nitrogen atmosphere (oxygen concentration: 200 ppm or less), to obtain a colorless and transparent polyimide film/glass laminate. Subsequently, the obtained polyimide film/glass laminate was immersed in water, and then the polyimide film was peeled from the glass and dried, to obtain a polyimide film having a thickness of about 10 μm.

The results of the measurements of the properties of the polyimide film are shown in Table 2-1.

### Example 81

5.1 g of the strontium carbonate dispersion (5), 18.54 g of water and 2.11 g (0.0220 mol) of 1,2-dimethylimidazole were placed in a reaction vessel, which was purged with nitrogen gas, and the mixture was stirred at room temperature for 1 hour. 1.14 g (0.0100 mol) of 1,4-tra-DACH was added to the resulting solution, and then the mixture was stirred at room temperature for 1 hour. 2.87 g (0.00975 mol) of s-BPDA and 0.07 g (0.00025 mol) of a-BPDA were gradually added to the resulting solution. The mixture was stirred at room temperature for 12 hours, to obtain a viscous polyimide precursor solution.

The polyimide precursor solution was applied on a glass substrate, and then the polyimide precursor was thermally imidized by heating the polyimide precursor solution on the glass substrate from room temperature to 350° C. in a nitrogen atmosphere (oxygen concentration: 200 ppm or less), to obtain a colorless and transparent polyimide film/glass laminate. Subsequently, the obtained polyimide film/glass laminate was immersed in water, and then the polyimide film was peeled from the glass and dried, to obtain a polyimide film having a thickness of about 10 μm.

The results of the measurements of the properties of the polyimide film are shown in Table 2-2.

### Comparative Example 2

11.42 g (0.100 mol) of 1,4-tra-DACH was placed in a reaction vessel, which was purged with nitrogen gas, and 231.37 g of water was added thereto such that the total mass of the charged monomers (total mass of the diamine component and the carboxylic acid component) was 15 mass %, and then the mixture was stirred at room temperature for 1 hour. 21.15 g (0.220 mol) of 1,2-dimethylimidazole was added to the resulting solution, and then the mixture was stirred at room temperature for 1 hour. 28.67 g (0.0975 mol) of s-BPDA and 0.74 g (0.0025 mol) of a-BPDA were gradually added to the resulting solution. The mixture was stirred at 50° C. for 12 hours, to obtain a homogeneous and viscous polyimide precursor solution.

The polyimide precursor solution was applied on a glass substrate, and then the polyimide precursor was thermally imidized by heating the polyimide precursor solution on the glass substrate from room temperature to 350° C. in a nitrogen atmosphere (oxygen concentration: 200 ppm or less), to obtain a colorless and transparent polyimide film/glass laminate. Subsequently, the obtained polyimide film/glass laminate was immersed in water, and then the polyimide film was peeled from the glass and dried, to obtain a polyimide film having a thickness of about 10 μm.

The results of the measurements of the properties of the polyimide film are shown in Table 2-2.

### Example 9

20.02 g (0.100 mol) of 4,4′-ODA was placed in a reaction vessel, which was purged with nitrogen gas, and 207.21 g of N,N-dimethylacetamide was added thereto such that the total mass of the charged monomers (total mass of the diamine component and the carboxylic acid component) was 17 mass %, and then the mixture was stirred at room temperature for 1 hour. 22.41 g (0.100 mmol) of PMDA-HS was gradually added to the resulting solution. The mixture was stirred at room temperature for 12 hours. 30 g of toluene was added to the resulting solution, and then the mixture was heated at 180° C. for 8 hours, to effect imidization. The resulting solution was re-precipitated into a large amount of water and filtered, and then dried. 10 g of the obtained solid (polyimide) was added to 40 g of N-methyl-2-pyrrolidone, and then the mixture was stirred at room temperature for 3 hours, to obtain a homogeneous and viscous polyimide solution. 5.0 g of the strontium carbonate dispersion (2) was added to the resulting solution, and then the mixture was stirred at room temperature for 1 hour, to obtain a polyimide solution.

The polyimide solution was applied on a glass substrate, and then the imidization was thermally performed by heating the polyimide solution on the glass substrate from room temperature to 350° C. in a nitrogen atmosphere (oxygen concentration: 200 ppm or less), to obtain a colorless and transparent polyimide film/glass laminate. Subsequently, the obtained polyimide film/glass laminate was immersed in water, and then the polyimide film was peeled from the glass and dried, to obtain a polyimide film having a thickness of about 10 μm.

The results of the measurements of the properties of the polyimide film are shown in Table 2-2.

### Example 101

20.02 g (0.100 mol) of 4,4′-ODA was placed in a reaction vessel, which was purged with nitrogen gas, and 207.21 g of N,N-dimethylacetamide was added thereto such that the total mass of the charged monomers (total mass of the diamine component and the carboxylic acid component) was 17 mass %, and then the mixture was stirred at room temperature for 1 hour. 22.41 g (0.100 mmol) of PMDA-HS was gradually added to the resulting solution. The mixture was stirred at room temperature for 12 hours. 30 g of toluene was added to the resulting solution, and then the mixture was heated at 180° C. for 8 hours, to effect imidization. The resulting solution was re-precipitated into a large amount of water and filtered, and then dried. 10 g of the obtained solid (polyimide) was added to 25 g of N-methyl-2-pyrrolidone, and then the mixture was stirred at room temperature for 3 hours, to obtain a homogeneous and viscous polyimide solution. 20.0 g of the strontium carbonate dispersion (2) was added to the resulting solution, and then the mixture was stirred at room temperature for 1 hour, to obtain a polyimide solution.

The polyimide solution was applied on a glass substrate, and then the imidization was thermally performed by heating the polyimide solution on the glass substrate from room temperature to 350° C. in a nitrogen atmosphere (oxygen concentration: 200 ppm or less), to obtain a colorless and transparent polyimide film/glass laminate. Subsequently, the obtained polyimide film/glass laminate was immersed in water, and then the polyimide film was peeled from the glass and dried, to obtain a polyimide film having a thickness of about 10 μm.

The results of the measurements of the properties of the polyimide film are shown in Table 2-2.

### Comparative Example 3

20.02 g (0.100 mol) of 4,4′-ODA was placed in a reaction vessel, which was purged with nitrogen gas, and 207.21 g of N,N-dimethylacetamide was added thereto such that the total mass of the charged monomers (total mass of the diamine component and the carboxylic acid component) was 17 mass %, and then the mixture was stirred at room temperature for 1 hour. 22.41 g (0.100 mmol) of PMDA-HS was gradually added to the resulting solution. The mixture was stirred at room temperature for 12 hours. 30 g of toluene was added to the resulting solution, and then the mixture was heated at 180° C. for 8 hours, to effect imidization. The resulting solution was re-precipitated into a large amount of water and filtered, and then dried. 10 g of the obtained solid (polyimide) was added to 40 g of N-methyl-2-pyrrolidone, and then the mixture was stirred at room temperature for 3 hours, to obtain a homogeneous and viscous polyimide solution.

The polyimide solution was applied on a glass substrate, and then the imidization was thermally performed by heating the polyimide solution on the glass substrate from room temperature to 350° C. in a nitrogen atmosphere (oxygen concentration: 200 ppm or less), to obtain a colorless and transparent polyimide film/glass laminate. Subsequently, the obtained polyimide film/glass laminate was immersed in water, and then the polyimide film was peeled from the glass and dried, to obtain a polyimide film having a thickness of about 10 μm.

The results of the measurements of the properties of the polyimide film are shown in Table 2-2.

### Example 11

7.20 g of the strontium carbonate dispersion (1) and 22.30 g of N-methyl-2-pyrrolidone were placed in a reaction vessel, which was purged with nitrogen gas, and the mixture was stirred at room temperature for 1 hour. 3.20 g (0.010 mol) of TFMB was placed in the reaction vessel, which was purged with nitrogen gas, and the mixture was stirred at room temperature for 1 hour. 0.88 g (0.0030 mol) of s-BPDA and 3.11 g (0.0070 mol) of 6FDA were gradually added to the resulting solution. The mixture was stirred at room temperature for 12 hours. 0.96 g (0.010 mol) of 1,2-dimethylimidazole was added to the resulting solution, and then the mixture was stirred at room temperature for 1 hour, to obtain a homogeneous and viscous polyimide precursor solution.

The polyimide precursor solution was applied on a glass substrate, and then the polyimide precursor was thermally imidized by heating the polyimide precursor solution on the glass substrate from room temperature to 350° C. in a nitrogen atmosphere (oxygen concentration: 200 ppm or less), to obtain a colorless and transparent polyimide film/glass laminate. Subsequently, the obtained polyimide film/glass laminate was immersed in water, and then the polyimide film was peeled from the glass and dried, to obtain a polyimide film having a thickness of about 10 μm.

The results of the measurements of the properties of the polyimide film are shown in Table 2-2.

### Comparative Example 4

32.02 g (0.100 mol) of TFMB was placed in a reaction vessel, which was purged with nitrogen gas, and 287.79 g of N-methyl-2-pyrrolidone was added thereto such that the total mass of the charged monomers (total mass of the diamine component and the carboxylic acid component) was 20 mass %, and then the mixture was stirred at room temperature for 1 hour. 8.83 g (0.030 mol) of s-BPDA and 31.10 g (0.070 mol) of 6FDA were gradually added to the resulting solution. The mixture was stirred at room temperature for 12 hours. 0.96 g (0.010 mol) of 1,2-dimethylimidazole was added to the resulting solution, and then the mixture was stirred at room temperature for 1 hour, to obtain a homogeneous and viscous polyimide precursor solution.

The polyimide precursor solution was applied on a glass substrate, and then the polyimide precursor was thermally imidized by heating the polyimide precursor solution on the glass substrate from room temperature to 350° C. in a nitrogen atmosphere (oxygen concentration: 200 ppm or less), to obtain a colorless and transparent polyimide film/glass laminate. Subsequently, the obtained polyimide film/glass laminate was immersed in water, and then the polyimide film was peeled from the glass and dried, to obtain a polyimide film having a thickness of about 10 μm.

The results of the measurements of the properties of the polyimide film are shown in Table 2-2.

### Example 12

2.13 g of the strontium carbonate dispersion (1) and 31.24 g of N-methyl-2-pyrrolidone were placed in a reaction vessel, which was purged with nitrogen gas, and the mixture was stirred at room temperature for 1 hour. 2.12 g (0.01 mol) of m-TD was added to the resulting solution, and then the mixture was stirred at room temperature for 1 hour. 0.38 g (0.001 mol) of CpODA and 1.76 g (0.009 mol) of CBDA were gradually added to the resulting solution. The mixture was stirred at room temperature for 12 hours. 0.10 g (0.001 mol) of 1,2-dimethylimidazole was added to the resulting solution, and then the mixture was stirred at room temperature for 1 hour, to obtain a viscous polyimide precursor solution.

The polyimide precursor solution was applied on a glass substrate such that the final thickness was about 80 μm, and then pre-dried on a hot plate at 80° C. The obtained film was peeled from the glass substrate, and only two sides of the upper side and the lower side were fixed to a pin tenter, and then the polyimide precursor was thermally imidized by heating the film from room temperature to 260° C. in a nitrogen atmosphere (oxygen concentration: 200 ppm or less), to obtain a colorless and transparent polyimide film. The thickness of the obtained polyimide film was about 80 μm.

The results of the measurements of the properties of the polyimide film are shown in Table 2-2.

### Comparative Example 5

2.12 g (0.010 mol) of m-TD was placed in a reaction vessel, which was purged with nitrogen gas, and 31.24 g of DMAc was added thereto such that the total mass of the charged monomers (total mass of the diamine component and the carboxylic acid component) was 12 mass %, and then the mixture was stirred at room temperature for 1 hour. 1.76 g (0.009 mol) of CBDA and 0.38 g (0.001 mol) of CpODA were gradually added to the resulting solution. The mixture was stirred at room temperature for 12 hours. 0.1 g (0.001 mol) of 1,2-dimethylimidazole was added to the resulting solution, and then the mixture was stirred at room temperature for 1 hour, to obtain a homogeneous and viscous polyimide precursor solution.

The polyimide precursor solution was applied on a glass substrate such that the final thickness was about 80 μm, and then pre-dried on a hot plate at 80° C. The obtained film was peeled from the glass substrate, and only two sides of the upper side and the lower side were fixed to a pin tenter, and then the polyimide precursor was thermally imidized by heating the film from room temperature to 260° C. in a nitrogen atmosphere (oxygen concentration: 200 ppm or less), to obtain a colorless and transparent polyimide film. The thickness of the obtained polyimide film was about 80 μm.

The results of the measurements of the properties of the polyimide film are shown in Table 2-2.

TABLE 2-1

| | | | | | | | | | Comparative |
|---|---|---|---|---|---|---|---|---|---|
| | | Example 1 | Example 2 | Example 3 | Example 4 | Example 5 | Example 6 | Example 7 | Example 1 |
| Polyimide | CpODA//BAPB/PPD/DABAN | ∘ | ∘ | ∘ | ∘ | ∘ | ∘ | ∘ | ∘ |
| (precursor) | s-BPDA/a-BPDA//1,4-tra-DACH | | | | | | | | |
| solution | H-PMDA/4,4′-ODA | | | | | | | | |
| | 6FDA/s-BPDA//TFMB | | | | | | | | |
| | CBDA/CpODA//m-TD | | | | | | | | |
| Solvent | | NMP | NMP | NMP | NMP | NMP | NMP | NMP | NMP |
| SrCO₃ | Strontium carbonate dispersion (1) | ∘ | ∘ | ∘ | ∘ | | | | |
| dispersion | Strontium carbonate dispersion (2) | | | | | ∘ | ∘ | | |
| | Strontium carbonate dispersion (4) | | | | | | | ∘ | |
| | Strontium carbonate dispersion (5) | | | | | | | | |

| | | | | | | | | |
|---|---|---|---|---|---|---|---|---|
| Amount of SrCO₃ relative to 100 parts by weight | 10.0 | 5.0 | 20.0 | 50.0 | 5.0 | 10.0 | 9.7 | 0 |
| of Polyimide precursor/parts by weight | | | | | | | | |
| Amount of SrCO₃ relative to 100 parts by weight | 10.7 | 5.3 | 21.4 | 53.4 | 5.3 | 10.7 | 10.4 | 0 |
| of Polyimide/parts by weight | | | | | | | | |
| Rth/nm | 653 | 880 | 578 | 596 | 558 | 607 | 730 | 931 |
| Re/nm | 0 | 1 | 3 | 1 | 2 | 3 | 4 | 1 |
| Total light transmittance/% | 86 | 86 | 85 | 84 | 69 | 83 | 83 | 86 |
| 5% weight loss temperature/° C. | — | 491 | 480 | 472 | 498 | 492 | 491 | 503 |
| CTE (100-250° C.)/ppm · K⁻¹ | 17 | 18 | 21 | 23 | 16 | 16 | 16 | 15 |
| Tensile modulus of elasticity/GPa | — | 3.9 | 4.2 | 6.4 | — | 5.3 | 5.5 | 4.1 |
| Elongation at break/% | — | 14 | 10 | 0 | — | 6 | 8 | 12 |
| Strength at break/MPa | — | 189 | 160 | 24 | — | 144 | 162 | 199 |

TABLE 2-2

| | | | | | | | | | | Com- |
|---|---|---|---|---|---|---|---|---|---|---|
| | | | Comparative | | Example | Comparative | Example | Comparative | Example | parative |
| | | Example 8 | Example 2 | Example 9 | 10 | Example 3 | 11 | Example 4 | 12 | Example 5 |
| Polyimide | CpODA//BAPB/ | | | | | | | | | |
| (precursor) | PPD/DABAN | | | | | | | | | |
| solution | s-BPDA/a-BPDA// | ∘ | ∘ | | | | | | | |
| | 1,4-tra-DACH | | | | | | | | | |
| | H-PMDA/4,4′- | | | ∘ | ∘ | ∘ | | | | |
| | ODA | | | | | | | | | |
| | 6FDA/s- | | | | | | ∘ | ∘ | | |
| | BPDA//TFMB | | | | | | | | | |
| | CBDA/ | | | | | | | | ∘ | ∘ |
| | CpODA//m-TD | | | | | | | | | |
| Solvent | | water | water | NMP | NMP | NMP | NMP | NMP | NMP | NMP |
| SrCO₃ | Strontium carbonate | | | | | | ∘ | | ∘ | |
| dispersion | dispersion (1) | | | | | | | | | |
| | Strontium carbonate | | | ∘ | ∘ | | | | | |
| | dispersion (2) | | | | | | | | | |
| | Strontium carbonate | | | | | | | | | |
| | dispersion (4) | | | | | | | | | |
| | Strontium carbonate | ∘ | | | | | | | | |
| | dispersion (5) | | | | | | | | | |

| | | | | | | | | | |
|---|---|---|---|---|---|---|---|---|---|
| Amount of SrCO₃ relative to | 6.5 | 0 | — | — | — | 10.0 | 0 | 5.0 | 0 |
| 100 parts by weight of Polyimide | | | | | | | | | |
| precursor/parts by weight | | | | | | | | | |
| Amount of SrCO₃ relative to | 7.1 | 0 | 5.0 | 20.0 | 0 | 10.5 | 0 | 5.5 | 0 |
| 100 parts by weight of Polyimide/ | | | | | | | | | |
| parts by weight | | | | | | | | | |
| Rth/nm | 659 | 821 | 47 | 108 | 139 | 72 | 116 | 8 | 500 |
| Re/nm | 1 | 4 | 0 | 0 | 1 | 0 | 0 | 203 | 284 |
| Total light transmittance/% | 72 | 77 | 77 | 89 | 89 | 87 | 88 | 87 | 89 |
| 5% weight loss temperature/° C. | 488 | 476 | 446 | 403 | 442 | 508 | 539 | 480 | 478 |
| CTE (100-250° C.)/ppm · K⁻¹ | 18.2 | 17.6 | 47.9 | 65.6 | 42.9 | 27.9 | 28.8 | 21 | 19.2 |
| Tensile modulus of | — | — | — | 4.1 | 3.7 | 3.9 | 3.8 | — | — |
| elasticity/GPa | | | | | | | | | |
| Elongation at break/% | — | — | — | 5 | 8 | 11 | 7 | — | — |
| Strength at break/MPa | — | — | — | 111 | 120 | 138 | 140 | — | — |

### INDUSTRIAL APPLICABILITY

According to the present invention, there may be provided a polyimide composition which may be easily produced, and has a small retardation in the thickness direction and in the in-plane direction, and also has excellent transparency, mechanical properties, or heat resistance, or the like; and a precursor composition thereof. The polyimide composition has excellent transparency, mechanical properties, or heat resistance, or the like, and has a small retardation in the thickness direction and in the in-plane direction, and therefore may be suitably used for the formation of a substrate for a display, a touch panel, a solar battery, or the like, in particular.

1. A polyimide precursor composition, comprising:
a polyimide precursor (A1); and
a fine particle having an optical anisotropy (B).

2. The polyimide precursor composition according to claim 1, wherein the polyimide precursor (A1) comprises at least one repeating unit represented by the following chemical formula (1): 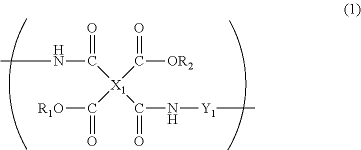
wherein X₁ is a tetravalent group having an aromatic ring or an alicyclic structure; Y₁ is a divalent group having an aromatic ring or an alicyclic structure; and R₁ and R₂ are each independently hydrogen, an alkyl group having 1 to 6 carbon atoms, or an alkylsilyl group having 3 to 9 carbon atoms.

3. The polyimide precursor composition according to claim 2, wherein a content of the repeating unit represented by the chemical formula (1) in which X₁ is a tetravalent group having an alicyclic structure and Y₁ is a divalent group having an alicyclic structure is 50 mol % or less relative to the total repeating units.

4. The polyimide precursor composition according to claim 2, wherein in the chemical formula (1), X₁ is a tetravalent group having an aromatic ring and Y₁ is a divalent group having an aromatic ring.

5. The polyimide precursor composition according to claim 2, wherein in the chemical formula (1), X₁ is a tetravalent group having an alicyclic structure and Y₁ is a divalent group having an aromatic ring.

6. The polyimide precursor composition according to claim 2, wherein in the chemical formula (1), X₁ is a tetravalent group having an aromatic ring and Y₁ is a divalent group having an alicyclic structure.

7. The polyimide precursor composition according to claim 1, wherein the fine particle having an optical anisotropy (B) is strontium carbonate.

8. A polyimide composition, comprising:
a polyimide (A2); and
a fine particle having an optical anisotropy (B).

9. The polyimide composition according to claim 8, wherein the polyimide (A2) comprises at least one repeating unit represented by the following chemical formula (7): 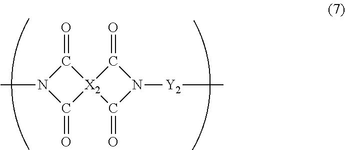
wherein X₂ is a tetravalent group having an aromatic ring or an alicyclic structure; and Y₂ is a divalent group having an aromatic ring or an alicyclic structure.

10. A polyimide composition obtained from the polyimide precursor composition according to claim 1.

11. A polyimide film consisting of the polyimide composition according to claim 8.

12. A polyimide film laminate, comprising:
the polyimide film according to claim 11; and
at least one glass layer.

13. A polyimide film laminate, comprising:
the polyimide film according to claim 11; and
at least one gas barrier layer.

14. A polyimide film laminate, comprising:
the polyimide film according to claim 11; and
at least one thin-film transistor.

15. A polyimide film laminate comprising:
the polyimide film according to claim 11; and
at least one conductive layer.

16. A film for a display, a touch panel, or a solar battery, comprising
the polyimide composition according to claim 8.

17. A display device, a sensor device, a photoelectric conversion device, or an optical device, comprising
the polyimide composition according to claim 8.

18. A fine particle powder having an optical anisotropy, which is surface-treated with a polyamic acid (A3) comprising a repeating unit represented by the following chemical formula (8): 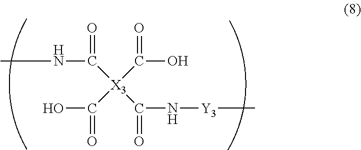
wherein X₃ is a tetravalent group having an aromatic ring or an alicyclic structure; and Y₃ is a divalent group having an aromatic ring or an alicyclic structure; with the proviso that the carboxyl group (—COOH) in the formula may form a salt with a base.

19. A fine particle dispersion, comprising:
a polyamic acid (A3) comprising a repeating unit represented by the following chemical formula (8): 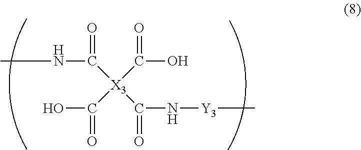
wherein X₃ is a tetravalent group having an aromatic ring or an alicyclic structure; and Y₃ is a divalent group having an aromatic ring or an alicyclic structure; with the proviso that the carboxyl group (—COOH) in the formula may form a salt with a base;
a fine particle having an optical anisotropy (B); and
a solvent (C).
